(19) United States
(12) Patent Application Publication
(10) Pub. No.: US 2025/0241049 A1
(43) Pub. Date: Jul. 24, 2025

(54) CAPACITOR STRUCTURE AND SEMICONDUCTOR PACKAGE INCLUDING THE SAME

(71) Applicant: Samsung Electronics Co., Ltd., Suwon-si (KR)

(72) Inventor: Choongjae Lee, Suwon-si (KR)

(21) Appl. No.: 18/973,272

(22) Filed: Dec. 9, 2024

(30) Foreign Application Priority Data
Jan. 18, 2024 (KR) 10-2024-0008293

(51) Int. Cl. H10D 80/20; H01L 25/18; H10D 1/68

(52) U.S. Cl. CPC H10D 80/215; H01L 25/18; H10D 1/714; H10D 1/716

(57) ABSTRACT

A capacitor structure includes a base substrate, a through via extending in a vertical direction from a top surface of the base substrate to a bottom surface of the base substrate, a first sub-capacitor structure disposed on the bottom surface of the base substrate and including a first lower electrode electrically connected to a first end of the through via, a first upper electrode, and a first capacitor dielectric layer between the first lower electrode and the first upper electrode, and a second sub-capacitor structure disposed on the top surface of the base substrate and including a second lower electrode electrically connected to a second end, opposite to the first end, of the through via, a second upper electrode, and a second capacitor dielectric layer between the second lower electrode and the second upper electrode on the top surface of the base substrate.

### CROSS-REFERENCE TO RELATED APPLICATION

This application is based on and claims priority under 35 U.S.C. § 119 to Korean Patent Application No. 10-2024-0008293, filed on Jan. 18, 2024, in the Korean Intellectual Property Office, the disclosure of which is incorporated by reference herein in its entirety.

### BACKGROUND

The inventive concept relates to a capacitor structure and a semiconductor package including the same.

In accordance with the rapid development of electronics industry and user demands, high-performance and miniaturized electronic devices have been achieved. Accordingly, high-performance and miniaturized semiconductor chips have also been achieved. Accordingly, capacitor structures used for various purposes such as energy storage, signal coupling/decoupling, and electronic filtering are attached to semiconductor packages including semiconductor chips.

### SUMMARY

The inventive concept relates to a capacitor structure having improved rated votlage characteristics and/or increased capacitance, and a semiconductor package including the capacitor structure.

According to an aspect of the present disclosure, a capacitor structure includes a base substrate, a through via extending in a vertical direction from a top surface of the base substrate to a bottom surface of the base substrate, wherein the vertical direction is perpendicular to the top surface of the base substrate, a first sub-capacitor structure disposed on the bottom surface of the base substrate and including a first lower electrode electrically connected to a first end of the through via, a first upper electrode, and a first capacitor dielectric layer between the first lower electrode and the first upper electrode, wherein the first end of the through via is exposed at the bottom surface of the base substrate, and a second sub-capacitor structure disposed on the top surface of the base substrate and including a second lower electrode electrically connected to a second end, opposite to the first end, of the through via, a second upper electrode, and a second capacitor dielectric layer between the second lower electrode and the second upper electrode on the top surface of the base substrate. The second end of the through via is exposed at the top surface of the base substrate. The base substrate is interposed between the first sub-capacitor structure and the second sub-capacitor structure.

According to an aspect of the present disclosure, a capacitor structure includes a base substrate, a first sub-capacitor structure disposed on a bottom surface of the base substrate and including a first lower electrode, a first upper electrode, and a first capacitor dielectric layer between the first lower electrode and the first upper electrode, a first mold layer disposed on the bottom surface of the base substrate and surrounding the first sub-capacitor structure, a second sub-capacitor structure disposed on a top surface of the base substrate and including a second lower electrode, a second upper electrode, and a second capacitor dielectric layer between the second lower electrode and the second upper electrode, a second mold layer disposed on the top surface of the base substrate and surrounding the second sub-capacitor structure, wherein the base substrate is interposed between the first sub-capacitor structure and the second sub-capacitor structure and between the first mold layer and the second mold layer, at least two through vias extending from the top surface of the base substrate to the bottom surface of the base substrate in a vertical direction which is perpendicular to the top surface of the base substrate, a first bump structure arranged on the second upper electrode and electrically connected to the second upper electrode, and a second bump structure arranged on the second mold layer. The at least two through vias include a first through via electrically connecting the first lower electrode to the second lower electrode.

According to an aspect of the present disclosure, a semiconductor package includes a package substrate including a first substrate, a plurality of top surface pads arranged on a top surface of the first substrate, and a plurality of bottom surface connection pads and at least two passive element connection pads arranged on a bottom surface of the first substrate, a semiconductor chip attached to the top surface of the first substrate and electrically connected to the package substrate through the plurality of top surface pads, an encapsulant disposed on the top surface of the first substrate and surrounding the semiconductor chip, a plurality of external connection terminals attached to the plurality of bottom surface connection pads, and a capacitor structure attached to the bottom surface of the first substrate. The capacitor structure includes a second substrate, a first sub-capacitor structure including a first base conductive layer, a plurality of first conductive pillars connected to a bottom surface of the first base conductive layer and spaced apart from one another in a horizontal direction which is parallel to a top surface of the second substrate, a first capacitor dielectric layer covering the first base conductive layer and each of the plurality of first conductive pillars, and a first upper electrode covering the first capacitor dielectric layer, which are sequentially arranged under a bottom surface of the second substrate, a second sub-capacitor structure including a second base conductive layer sequentially arranged on the top surface of the second substrate, a plurality of second conductive pillars connected to a top surface of the second base conductive layer and spaced apart from one another in the horizontal direction, a second capacitor dielectric layer covering the second base conductive layer and each of the plurality of second conductive pillars, and a second upper electrode covering the second capacitor dielectric layer, a through via extending from the top surface of the second substrate to the bottom surface of the second substrate in a vertical direction which is perpendicular to the top surface of the second substrate and electrically connecting the first base conductive layer to the second base conductive layer, and at least two bump structures attached to the at least two passive element connection pads. One of the at least two bump structures is arranged on the second upper electrode to be electrically connected to the second upper electrode. The first sub-capacitor structure and the second sub-capacitor structure are symmetrical to each other in the vertical direction.

### BRIEF DESCRIPTION OF THE DRAWINGS

Embodiments will be more clearly understood from the following detailed description taken in conjunction with the accompanying drawings in which:

FIGS. 1A to 1J are cross-sectional views illustrating a method of manufacturing a capacitor structure and a capacitor structure manufactured by the method, according to an embodiment;

FIGS. 2A to 2I are cross-sectional views illustrating a method of manufacturing a capacitor structure and a capacitor structure manufactured by the method, according to an embodiment;

FIGS. 3A to 3I are cross-sectional views illustrating a method of manufacturing a capacitor structure and a capacitor structure manufactured by the method, according to an embodiment;

FIGS. 4 to 11 are cross-sectional views illustrating a capacitor structure according to an embodiment;

FIG. 12 is a cross-sectional view illustrating a semiconductor package including a capacitor structure according to an embodiment; and

FIG. 13 is a cross-sectional view illustrating a semiconductor package including a capacitor structure according to an embodiment.

### DETAILED DESCRIPTION OF THE EMBODIMENTS

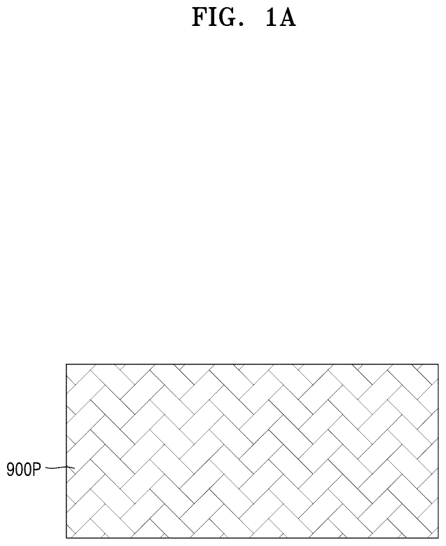

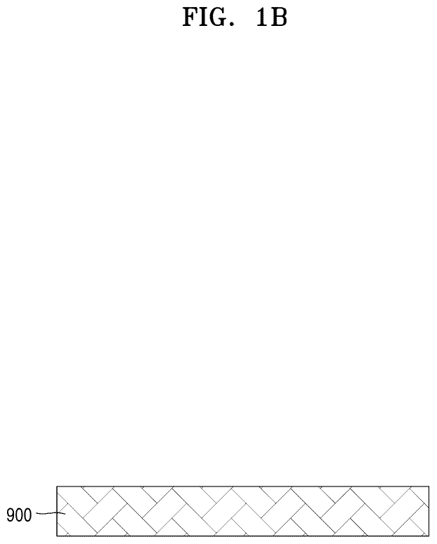

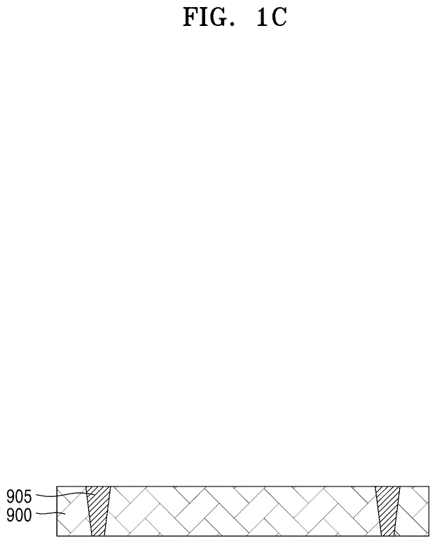

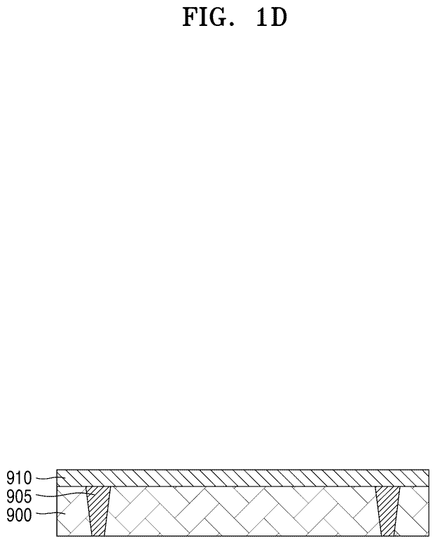

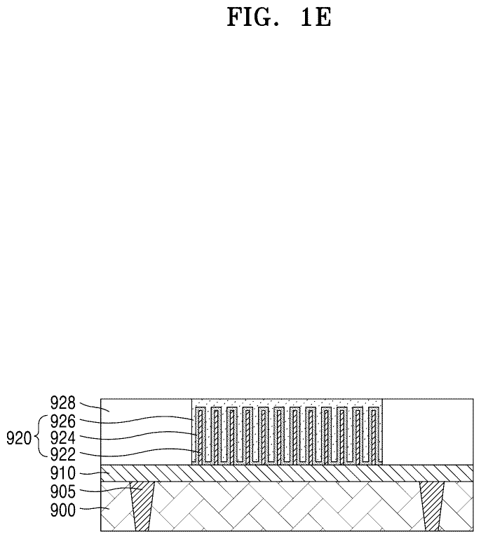

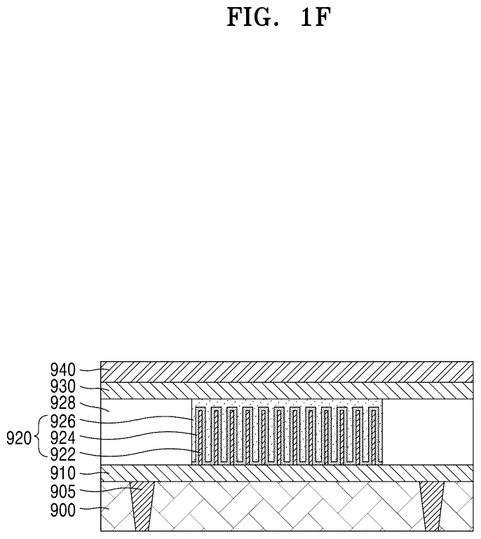

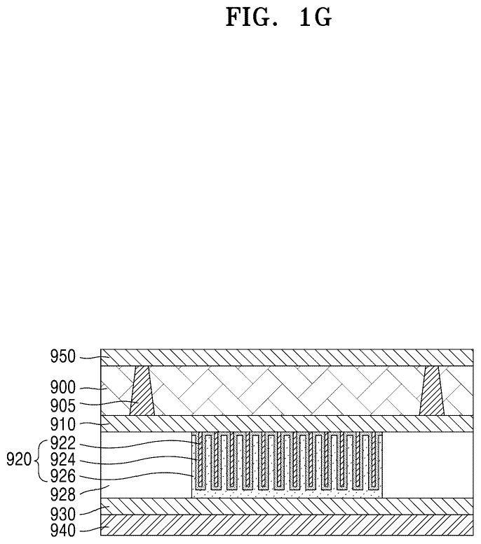

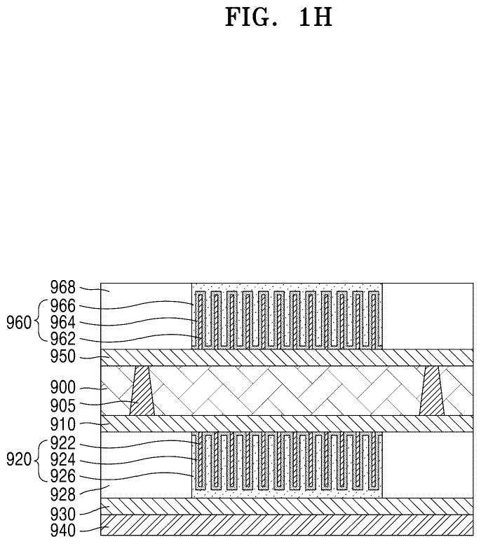

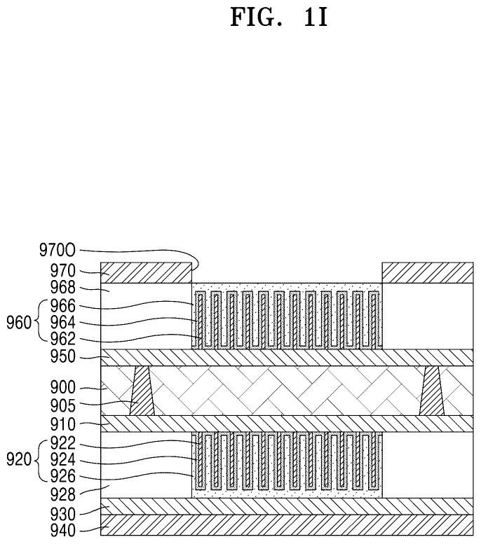

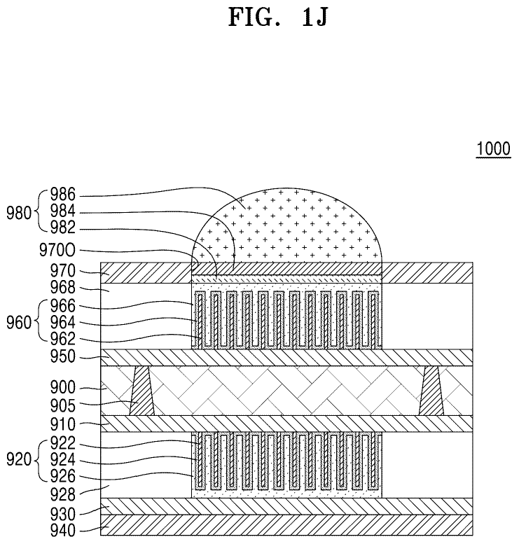

FIGS. 1A to 1J are cross-sectional views illustrating a method of manufacturing a capacitor structure 1000 and a capacitor structure 1000 manufactured by the method according to an embodiment.

Referring to FIG. 1A, a preliminary base substrate 900P is prepared. The preliminary base substrate 900P may include or may be formed of, for example, silicon (Si). In some embodiments, the preliminary base substrate 900P may include or may be formed of a semiconductor material such as germanium (Ge), or a compound semiconductor material such as silicon carbide (SiC), gallium arsenide (GaAs), indium arsenide (InAs), and indium phosphide (InP). In some embodiments, the preliminary base substrate 900P may be a silicon wafer having a thickness of 725 μm±25 μm.

Referring to FIGS. 1A and 1B together, part of the preliminary base substrate 900P is removed to form a base substrate 900. For example, the base substrate 900 may be formed by grinding the preliminary base substrate 900P to reduce the thickness of the preliminary base substrate 900P. The base substrate 900 may be formed to have a thickness of about 50 μm to about 70 μm. However, the inventive concept is not limited thereto. For example, the base substrate 900 may have a thickness of about 50 μm to about 700 μm.

Referring to FIG. 1C, a through via 905 is formed through the base substrate 900. The through via 905 may extend in a vertical direction from a top surface of the base substrate 900 to a bottom surface of the base substrate 900. The through via 905 may be formed to have a horizontal width of about 3 μm to about 20 μm. The through via 905 may be formed to have a tapered shape of which a horizontal width and a horizontal area decrease from the top surface of the base substrate 900 to the bottom surface of the base substrate 900. The through via 905 may include or may be formed of a metal, an alloy, conductive metal nitride, or a combination thereof. For example, the through via 905 may include or may be formed of copper (Cu).

The through via 905 may be formed by forming a through via hole extending through the base substrate 900 and then filling the through via hole with a conductive material. The through via hole may be formed to have a width of about 3 μm to about 20 μm. In some embodiments, the through via 905 may include a barrier layer covering an internal sidewall of the through via hole and a conductive layer covering the barrier layer. For example, the barrier layer may include or may be formed of at least one material selected from titanium (Ti), titanium nitride (TiN), tantalum (Ta), tantalum nitride (TaN), ruthenium (Ru), cobalt (Co), manganese (Mn), tungsten nitride (WN), nickel (Ni), and nickel boride (NiB). In some embodiments, a physical vapor deposition (PVD), chemical vapor deposition (CVD), or atomic layer deposition (ALD) process may be used to form the barrier layer. For example, the barrier layer may be formed on an internal wall of the through via hole to have a thickness of about 40 Å to about 50 Å. The conductive layer may include or may be formed of Cu or a Cu alloy. In some embodiments, the conductive layer may include or may be formed of Co/Cu, Ni/Cu, or Ru/Cu. A plating process may be used to form the conductive layer. In some embodiments, an insulating layer may be interposed between the internal wall of the through via hole and the through via 905. The insulating layer may be formed to cover a surface of the base substrate 900 exposed to the internal wall of the through via hole with a uniform thickness. In some embodiments, the insulating layer may include or may be an oxide layer, a nitride layer, a carbonized layer, or a combination thereof. In some embodiments, a CVD process may be used to form the insulating layer. The insulating layer may be formed to have a thickness of about 500 Å to about 2,500 Å.

Referring to FIG. 1D, a first base conductive layer 910 is formed on the base substrate 900. The first base conductive layer 910 may include or may be formed of a metal. For example, the first base conductive layer 910 may include or may be formed of Cu, aluminum (Al), W, or Ti. In some embodiments, the first base conductive layer 910 may have a stacked structure of a plurality of conductive layers. Each of the plurality of conductive layers may include or may be formed of a metal, an alloy, or conductive metal nitride. The first base conductive layer 910 may be formed to have a thickness of about 3 μm to about 20 μm. The first base conductive layer 910 may contact the through via 905 and may be electrically connected to the through via 905.

Referring to FIG. 1E, a first sub-capacitor structure 920 and a first mold layer 928 surrounding the first sub-capacitor structure 920 are formed on the first base conductive layer 910. The first sub-capacitor structure 920 may include a plurality of first conductive pillars 922 which are electrically connected to the first base conductive layer 910 and spaced apart from one another, a first capacitor dielectric layer 924 covering the first base conductive layer 910 and each of the plurality of first conductive pillars 922, and a first upper electrode 926 covering the first capacitor dielectric layer 924. The first base conductive layer 910 and the plurality of first conductive pillars 922 may perform a function of a lower electrode of the first sub-capacitor structure 920 together and may be referred to as a first lower electrode corresponding to the first upper electrode 926 of the first sub-capacitor structure 920. For example, the first sub-capacitor structure 920 may include the first lower electrode, the first upper electrode 926, and the first capacitor dielectric layer 924 therebetween.

The plurality of first conductive pillars 922 may be spaced apart from one another in a horizontal direction and may be formed on the first base conductive layer 910. For example, the plurality of first conductive pillars 922 may be arranged in a matrix in horizontal row and columns, or in a honeycomb arrangement zigzag in one of the horizontal rows and columns. Each of the plurality of first conductive pillars 922 may have a circular pillar shape. However, the inventive concept is not limited thereto. For example, each of the plurality of first conductive pillars 922 may have a cylindrical shape with a closed lower portion, or a pillar shape having various horizontal cross-sections such as a tripod shape, a cross shape, and a macaroni shape. Each of the plurality of first conductive pillars 922 may be formed to have a horizontal width of about 100 nm to about 2 μm. Each of the plurality of first conductive pillars 922 may be formed to have a height of about 15 μm to about 40 μm. Each of the plurality of first conductive pillars 922 may include or may be formed of a metal. Each of the plurality of first conductive pillars 922 may include or may be formed of impurity-doped polysilicon, a metal, or a conductive metal compound. For example, each of the plurality of first conductive pillars 922 may include or may be formed of Cu, W, or TiN.

The first capacitor dielectric layer 924 may cover surfaces of the first base conductive layer 910 and the plurality of first conductive pillars 922. In some embodiments, the first capacitor dielectric layer 924 may conformally cover the surfaces of the first base conductive layer 910 and the plurality of first conductive pillars 922. For example, the first capacitor dielectric layer 924 may be formed so as not to completely fill spaces among the plurality of first conductive pillars 922. The first capacitor dielectric layer 924 may include or may be formed of silicon oxide or a high-k dielectric material including a dielectric material having a higher relative dielectric constant than silicon oxide. The high-k dielectric material may have a relative dielectric constant of about 10 to about 25. The high-k dielectrics may include at least one material selected from hafnium oxide (HfO), hafnium silicate (HfSiO), hafnium oxynitride (HfON), hafnium silicon oxynitride (HfSiON), lanthanum oxide (LaO), lanthanum oxynitride (LaON), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), titanium oxynitride (TiON), barium strontium titanium oxide (BaSrTiO), barium titanium oxide (BaTiO), strontium titanium oxide (SrTiO), yttrium oxide (YO), aluminum oxide (AlO), aluminum oxynitride (AlON), and lead scandium tantalum oxide (PbScTaO). For example, the first capacitor dielectric layer 924 may be formed to have a thickness of about 10 Å to about 100 nm.

The first upper electrode 926 may cover the first capacitor dielectric layer 924. The first capacitor dielectric layer 924 may be interposed between the first upper electrode 926 and the first base conductive layer 910 and between the first upper electrode 926 and each of the plurality of first conductive pillars 922. The first upper electrode 926 may include or may be formed of impurity-doped polysilicon, a metal, or a conductive metal compound. The first upper electrode 926 may be formed to completely fill the spaces among the plurality of first conductive pillars 922.

The first mold layer 928 may cover part of the first base conductive layer 910 and may surround the first sub-capacitor structure 920. For example, the first mold layer 928 may surround the first sub-capacitor structure 920 but may not cover a top surface of the first upper electrode 926. In some embodiments, a top surface of the first mold layer 928 and the top surface of the first upper electrode 926 may be at the same vertical level. The first mold layer 928 may include or may be formed of an insulating material. For example, the first mold layer 928 may include or may be formed of silicon oxide, silicon nitride, silicon oxynitride, or silicon carbonitride. In some embodiments, the first mold layer 928 may include or may be formed of tetra ethyl ortho silicate (TEOS) oxide or high density plasma (HDP) oxide.

Referring to FIG. 1F, a connection conductive layer 930 covering the top surface of the first mold layer 928 and the top surface of the first upper electrode 926 and a first protective layer 940 covering the connection conductive layer 930 are formed.

The connection conductive layer 930 may include or may be formed of a metal. For example, the connection conductive layer 930 may include or may be formed of Cu, Al, W, or Ti. In some embodiments, the connection conductive layer 930 may have a stacked structure of a plurality of conductive layers. Each of the plurality of conductive layers may include or may be formed of a metal, an alloy, or conductive metal nitride. The connection conductive layer 930 may be formed to have a thickness of about 3 μm to about 20 μm. The connection conductive layer 930 may contact the first upper electrode 926 and may be electrically connected to the first upper electrode 926. In some embodiments, the connection conductive layer 930 may be omitted.

The first protective layer 940 may include or may be formed of an insulating material. For example, the first protective layer 940 may include or may be formed of photosensitive polyimide (PSPI) or silicon nitride. The first protective layer 940 may be formed to have a thickness of about 10 μm to about 30 μm.

Referring to FIG. 1G, after turning the result of FIG. 1F upside down so that the base substrate 900 and the through via 905 face upward, a second base conductive layer 950 is formed on the base substrate 900 and the through via 905. The second base conductive layer 950 may include or may be formed of a metal. For example, the second base conductive layer 950 may include or may be formed of Cu, Al, W, or Ti. In some embodiments, the second base conductive layer 950 may have a stacked structure of a plurality of conductive layers. Each of the plurality of conductive layers may include or may be formed of a metal, an alloy, or conductive metal nitride. The second base conductive layer 950 may be formed to have a thickness of about 3 μm to about 20 μm. The second base conductive layer 950 may contact the through via 905 and may be electrically connected to the through via 905. A bottom surface of the through via 905 may contact a top surface of the first base conductive layer 910, and a top surface of the through via 905 may contact a bottom surface of the second base conductive layer 950.

Referring to FIG. 1H, a second sub-capacitor structure 960 and a second mold layer 968 surrounding the second sub-capacitor structure 960 are formed on the second base conductive layer 950. The second sub-capacitor structure 960 may include a plurality of second conductive pillars 962 which are connected to the second base conductive layer 950 and spaced apart from one another, a second capacitor dielectric layer 964 covering the second base conductive layer 950 and each of the plurality of second conductive pillars 962, and a second upper electrode 966 covering the second capacitor dielectric layer 964. The second base conductive layer 950 and the plurality of second conductive pillars 962 may perform a function of a lower electrode of the second sub-capacitor structure 960 together and may be referred to as a second lower electrode corresponding to the second upper electrode 966 of the second sub-capacitor structure 960. For example, the second sub-capacitor structure 960 may include the second lower electrode, the second upper electrode 966, and the second capacitor dielectric layer 964 therebetween.

Because the plurality of second conductive pillars 962, the second capacitor dielectric layer 964, the second upper electrode 966, and the second mold layer 968 formed on the second base conductive layer 950 are substantially the same as the plurality of first conductive pillars 922, the first capacitor dielectric layer 924, the first upper electrode 926, and the first mold layer 928 formed on the first base conductive layer 910, respectively, redundant contents may be omitted.

The first sub-capacitor structure 920 and the second sub-capacitor structure 960 may be symmetrical to each other in a vertical direction which is perpendicular to the top surface of the base substrate 900. The first sub-capacitor structure 920 and the second sub-capacitor structure 960 may be symmetrical to each other with respect to the base substrate 900 and the through via 905. For example, the first base conductive layer 910, the plurality of first conductive pillars 922, the first capacitor dielectric layer 924, and the first upper electrode 926 may be sequentially arranged from the base substrate 900 and the through via 905, and the second base conductive layer 950, the plurality of second conductive pillars 962, the second capacitor dielectric layer 964, and the second upper electrode 966 may be sequentially arranged from the base substrate 900 and the through via 905.

The first sub-capacitor structure 920 and the second sub-capacitor structure 960 may be electrically connected to each other through the through via 905. For example, the plurality of first conductive pillars 922 of the first sub-capacitor structure 920 may be electrically connected to the through via 905 through the first base conductive layer 910, and the plurality of second conductive pillars 962 of the second sub-capacitor structure 960 may be electrically connected to the through via 905 through the second base conductive layer 950.

Referring to FIG. 1I, a second protective layer 970 is formed to cover a top surface of the second mold layer 968 and to have a bump opening 970O. After forming a protective material layer covering the top surface of the second mold layer 968 and a top surface of the second upper electrode 966, part of the protective material layer covering at least part of the second upper electrode 966 may be removed to form the second protective layer 970 having the bump opening 970O. Part of the protective material layer covering at least part of the second upper electrode 966 may be removed to position the bump opening 970O. At least part of the second upper electrode 966 may be exposed through the bump opening 970O. In some embodiments, the bump opening 970O may expose the entirety of the second upper electrode 966.

Referring to FIG. 1J, a bump structure 980 is formed on the second upper electrode 966 exposed through the bump opening 970O to form the capacitor structure 1000. The capacitor structure 1000 may be a silicon capacitor. The bump structure 980 may be arranged on the second upper electrode 966 to be electrically connected to the second upper electrode 966. In some embodiments, the bump structure 980 may include a connection pad layer 982, an under-bump-metallization (UBM) layer 984 on the connection pad layer 982, and a conductive cap 986 on the UBM layer 984. However, the inventive concept is not limited thereto. For example, the bump structure 980 may include the conductive cap 986 but may not include at least one of the connection pad layer 982 and the UBM layer 984. The connection pad layer 982 may include or may be formed of a metal. For example, the connection pad layer 982 may include or may be formed of Cu, a copper alloy, Al, W, gold (Au), Ni, or a combination thereof. In some embodiments, the connection pad layer 982 may have a pillar shape with a relatively large thickness. The connection pad layer 982 may be formed by a plating process such as electrolytic plating and electroless plating. The UBM layer 984 may cover at least part of the connection pad layer 982. Although it is illustrated in FIG. 1J that the UBM layer 984 completely covers a top surface of the connection pad layer 982, the inventive concept is not limited thereto. For example, the UBM layer 984 may cover part of the top surface of the connection pad layer 982, for example, part adjacent to an edge of the top surface of the connection pad layer 982. The UBM layer 984 may include or may be formed of Ti, Cu, Ni, Au, NiV, NiP, TiNi, TiW, TaN, Al, palladium (Pd), CrCu, or a combination thereof. The conductive cap 986 may cover a top surface of the UBM layer 984. The conductive cap 986 may include or may be formed of a solder ball or a solder bump. For example, the conductive cap 986 may include or may be formed of silver (Ag), tin (Sn), Au, or solder. In some embodiments, the conductive cap 986 may include or may be formed of SnAg.

The capacitor structure 1000 according to an embodiment includes the first sub-capacitor structure 920 and the second sub-capacitor structure 960 connected to each other through the through via 905. The first sub-capacitor structure 920 and the second sub-capacitor structure 960 may overlap each other in the vertical direction. The first sub-capacitor structure 920 and the second sub-capacitor structure 960 may be symmetrical to each other with respect to the base substrate 900 and the through via 905. Therefore, according to an electrical connection method between the first sub-capacitor structure 920 and the second sub-capacitor structure 960, rated voltage characteristics of the capacitor structure 1000 may be improved or capacitance thereof may be increased.

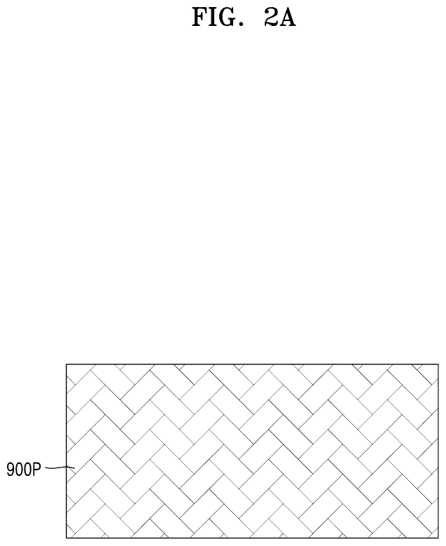

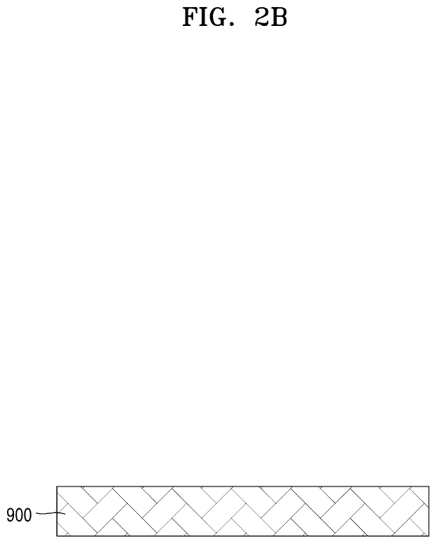

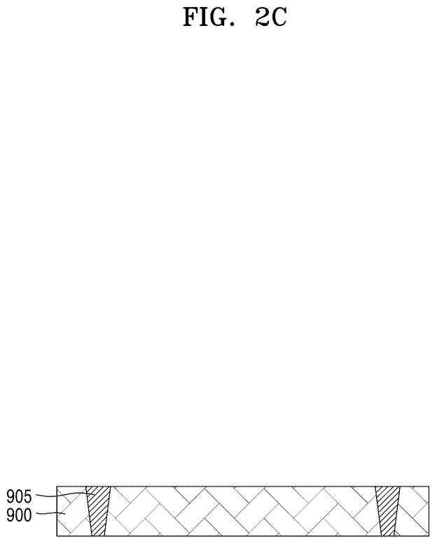

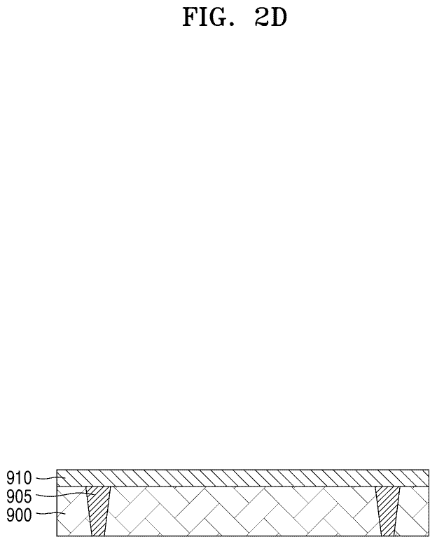

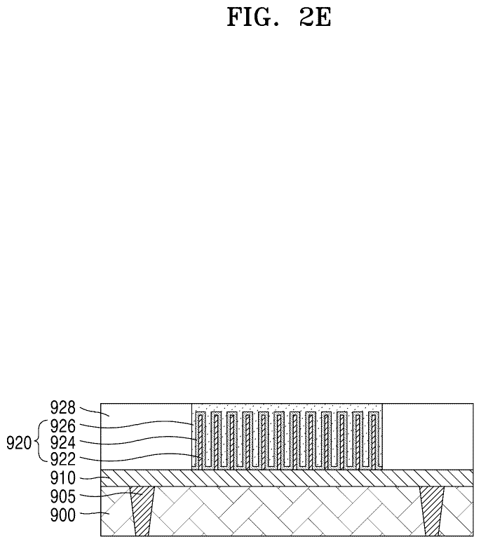

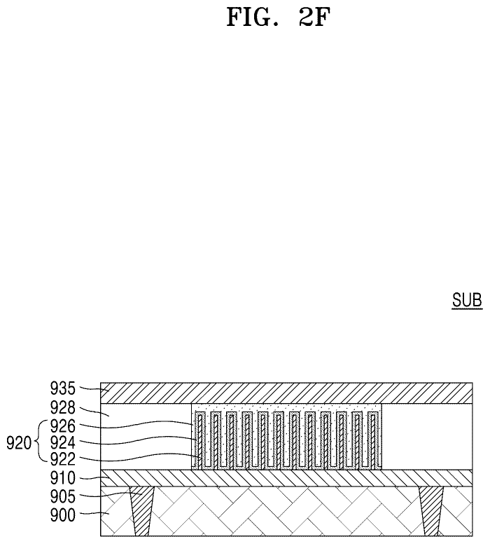

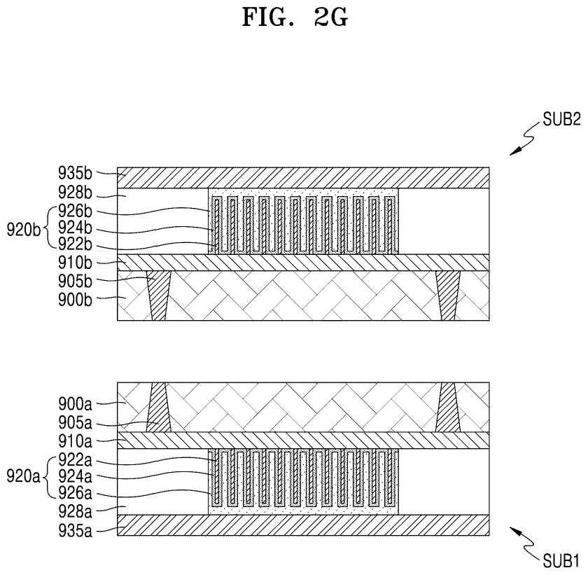

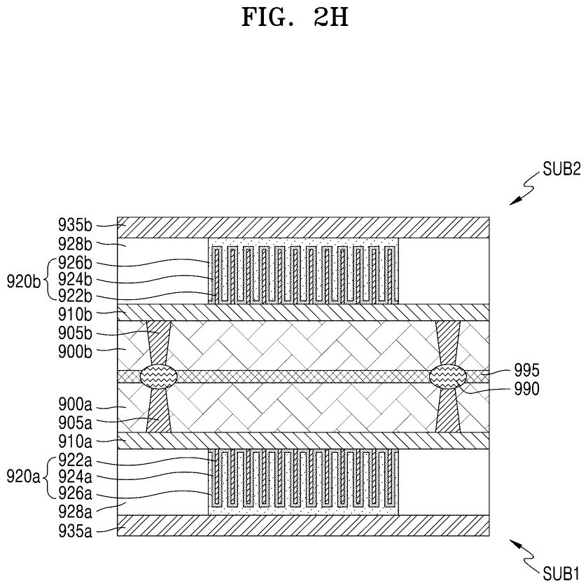

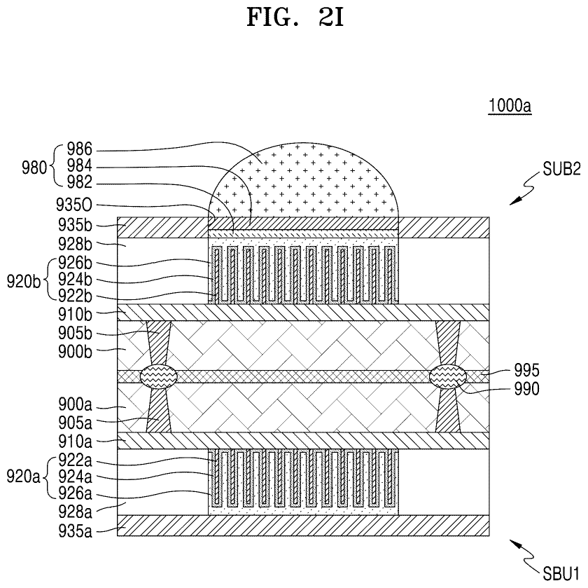

FIGS. 2A to 2I are cross-sectional views illustrating a method of manufacturing a capacitor structure 1000a and a capacitor structure 1000a manufactured by the method according to an embodiment.

Referring to FIG. 2A, a preliminary base substrate 900P is prepared. In some embodiments, the preliminary base substrate 900P may be a silicon wafer.

Referring to FIGS. 2A and 2B together, part of the preliminary base substrate 900P is removed to form a base substrate 900. For example, the base substrate 900 may be formed by grinding the preliminary base substrate 900P to reduce a thickness of the preliminary base substrate 900P.

Referring to FIG. 2C, a through via 905 is formed through the base substrate 900. The through via 905 may extend from a top surface of the base substrate 900 to a bottom surface of the base substrate 900. The through via 905 may be formed to have a tapered shape of which a horizontal width and a horizontal area decrease from the top surface of the base substrate 900 to the bottom surface of the base substrate 900.

Referring to FIG. 2D, a base conductive layer 910 is formed on the base substrate 900. The base conductive layer 910 may contact the through via 905 and may be electrically connected to the through via 905.

Referring to FIG. 2E, a sub-capacitor structure 920 and a mold layer 928 surrounding the sub-capacitor structure 920 are formed on the base conductive layer 910. The sub-capacitor structure 920 is electrically connected to the base conductive layer 910 and may include a plurality of conductive pillars 922 which are spaced apart from one another, a capacitor dielectric layer 924 covering the base conductive layer 910 and each of the plurality of conductive pillars 922, and an upper electrode 926 covering the capacitor dielectric layer 924. The base conductive layer 910 and the plurality of conductive pillars 922 may perform a function of a lower electrode of the sub-capacitor structure 920 together and may be referred to as a lower electrode corresponding to the upper electrode 926 of the sub-capacitor structure 920. For example, the sub-capacitor structure 920 may include the lower electrode, the upper electrode 926, and the capacitor dielectric layer 924 disposed therebetween.

The plurality of conductive pillars 922 may be spaced apart from one another in the horizontal direction and may be formed on the base conductive layer 910. The capacitor dielectric layer 924 may cover surfaces of the base conductive layer 910 and the plurality of conductive pillars 922. The upper electrode 926 may cover the capacitor dielectric layer 924. The upper electrode 926 may be formed to completely fill the spaces among the plurality of conductive pillars 922. The mold layer 928 may cover part of the base conductive layer 910 and may surround the sub-capacitor structure 920.

Referring to FIG. 2F, a protective layer 935 covering a top surface of the mold layer 928 and a top surface of the upper electrode 926 is formed to form a sub-structure SUB. The protective layer 935 may include or may be formed of an insulating material.

Referring to FIG. 2G, a first sub-structure SUB1 and a second sub-structure SUB2 are prepared. The first sub-structure SUB1 may include a first base substrate 900a, a first sub-capacitor structure 920a including a first through via 905a, a first base conductive layer 910a, a plurality of first conductive pillars 922a, a first capacitor dielectric layer 924a, and a first upper electrode 926a, a first mold layer 928a, and a first protective layer 935a. The second sub-structure SUB2 may include a second base substrate 900b, a second sub-capacitor structure 920b including a second through via 905b, a second base conductive layer 910b, a plurality of second conductive pillars 922b, a second capacitor dielectric layer 924b, and a second upper electrode 926b, a second mold layer 928b, and a second protective layer 935b.

Each of the first sub-structure SUB1 and the second sub-structure SUB2 may be substantially the same as the sub-structure SUB illustrated in FIG. 2F. Each of the first base substrate 900a and the second base substrate 900b may be substantially the same as the base substrate 900 illustrated in FIG. 2F. Each of the first through via 905a and the second through via 905b may be substantially the same as the through via 905 illustrated in FIG. 2F. Each of the first base conductive layer 910a and the second base conductive layer 910b may be substantially the same as the base conductive layer 910 illustrated in FIG. 2F. Each of the plurality of first conductive pillars 922a and the plurality of second conductive pillars 922b may be substantially the same as the plurality of conductive pillars 922 illustrated in FIG. 2F. Each of the first capacitor dielectric layer 924a and the second capacitor dielectric layer 924b may be substantially the same as the capacitor dielectric layer 924 illustrated in FIG. 2F. Each of the first upper electrode 926a and the second upper electrode 926b may be substantially the same as the upper electrode 926 illustrated in FIG. 2F. Each of the first sub-capacitor structure 920a and the second sub-capacitor structure 920b may be substantially the same as the sub-capacitor structure 920 illustrated in FIG. 2F. Each of the first mold layer 928a and the second mold layer 928b may be substantially the same as the mold layer 928 illustrated in FIG. 2F. Each of the first protective layer 935a and the second protective layer 935b may be substantially the same as the protective layer 935 illustrated in FIG. 2F.

For example, the first sub-structure SUB1 may be the sub-structure SUB illustrated in FIG. 2F flipped upside down, and the second sub-structure SUB2 may be the sub-structure SUB illustrated in FIG. 2F. The first sub-structure SUB1 and the second sub-structure SUB2 may be arranged so that the first base substrate 900a and the second base substrate 900b face each other, and the first through via 905a and the second through via 905b face each other.

Referring to FIG. 2H, the first through via 905a and the second through via 905b are connected to each other by a connection bump 990. For example, the connection bump 990 may include or may be formed of Ag, Sn, Au, or solder. In some embodiments, the connection bump 990 may include or may be formed of SnAg.

An insulating adhesive layer 995 may be interposed between the first sub-structure SUB1 and the second sub-structure SUB2. The insulating adhesive layer 995 may surround the connection bump 990, and may fill a space between the first sub-structure SUB1 and the second sub-structure SUB2, that is, between the first base substrate 900a and the second base substrate 900b. The insulating adhesive layer 995 may include or may be a non-conductive film (NCF), a die attach film (DAF), non-conductive paste (NCP), insulating polymer, or epoxy resin.

Referring to FIG. 2I, after removing part of the second protective layer 935b to form a bump opening 935O, a bump structure 980 is formed on the second upper electrode 926b exposed through the bump opening 935O to form the capacitor structure 1000a. In some embodiments, the bump structure 980 may include a connection pad layer 982, a UBM layer 984 on the connection pad layer 982, and a conductive cap 986 on the UBM layer 984. However, the inventive concept is not limited thereto.

The capacitor structure 1000a according to an embodiment includes the first sub-capacitor structure 920a and the second sub-capacitor structure 920b electrically connected to each other through the first through via 905a and the second through via 905b. The first through via 905a and the second through via 905b may be electrically connected to each other through the connection bump 990. Each of the first through via 905a and the second through via 905b may have a tapered shape of which a horizontal width and a horizontal area decrease toward the connection bump 990. In other words, the tapered shape may have the horizontal width and the horizontal area which increases away from the connection bump 990. The first through via 905a and the second through via 905b may be symmetrical to each other in the vertical direction. The first through via 905a and the second through via 905b may be symmetrical to each other with respect to the connection bump 990.

The first sub-capacitor structure 920a and the second sub-capacitor structure 920b may overlap each other in the vertical direction. The first sub-capacitor structure 920a and the second sub-capacitor structure 920b may be symmetrical to each other in the vertical direction. The first base substrate 900a and the second base substrate 900b may be referred to as a base substrate, and the first through via 905a and the second through via 905b may be referred to as a through via. The through via may pass through the base substrate. The first sub-capacitor structure 920a and the second sub-capacitor structure 920b may be symmetrical to each other with respect to the first base substrate 900a and the second base substrate 900b, and the first through via 905a and the second through via 905b. That is, the first sub-capacitor structure 920a and the second sub-capacitor structure 920b may be symmetrical to each other with respect to the base substrate and the through via.

The capacitor structure 1000a according to an embodiment includes the first sub-capacitor structure 920a and the second sub-capacitor structure 920b connected to each other through the first through via 905a and the second through via 905b. Therefore, according to an electrical connection method between the first sub-capacitor structure 920a and the second sub-capacitor structure 920b, rated voltage characteristics of the capacitor structure 1000a may be improved or capacitance thereof may be increased.

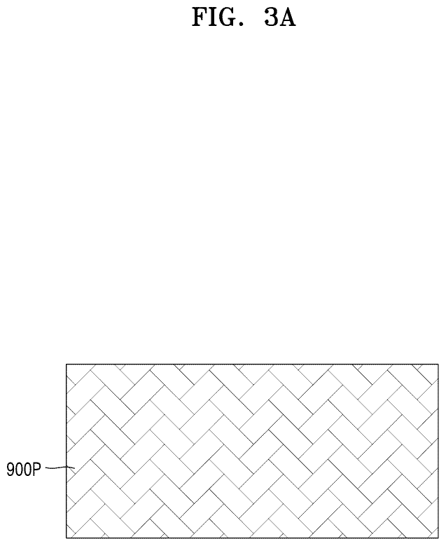

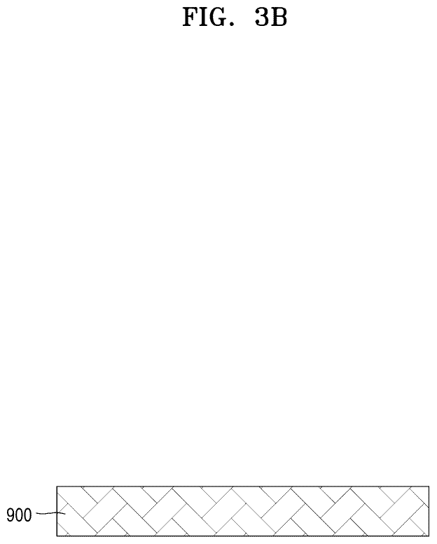

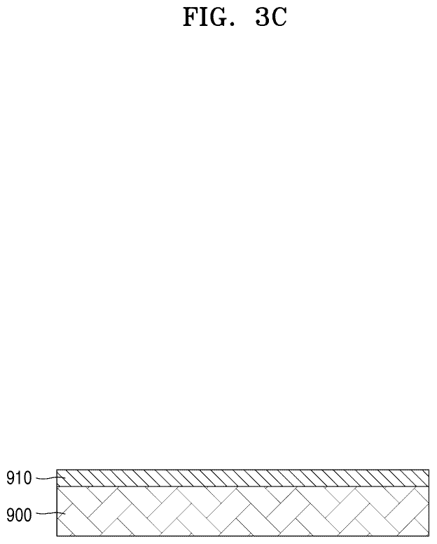

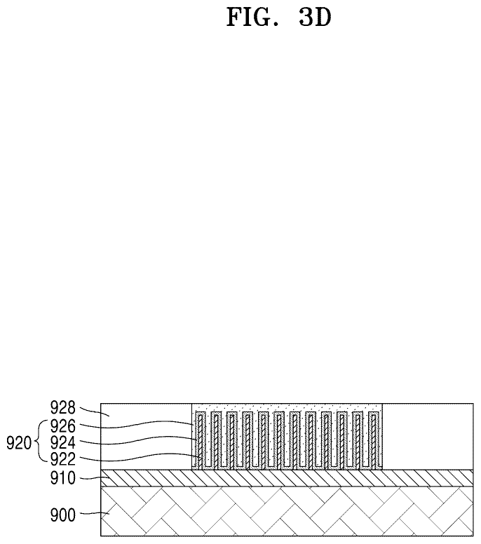

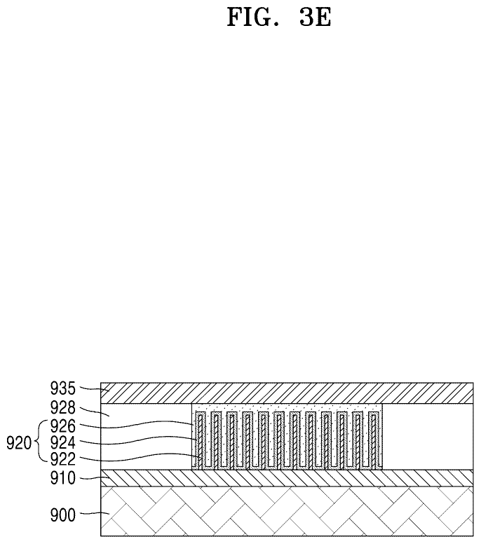

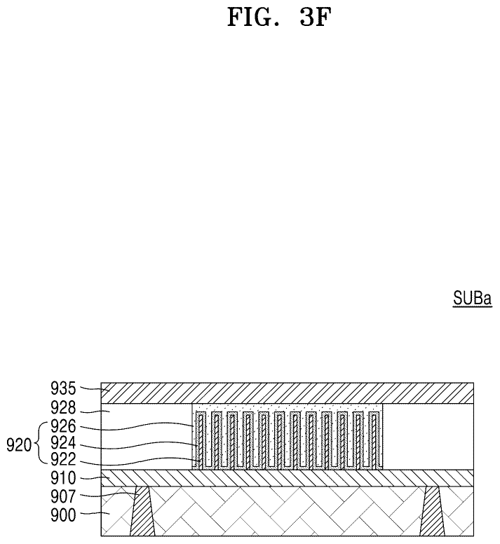

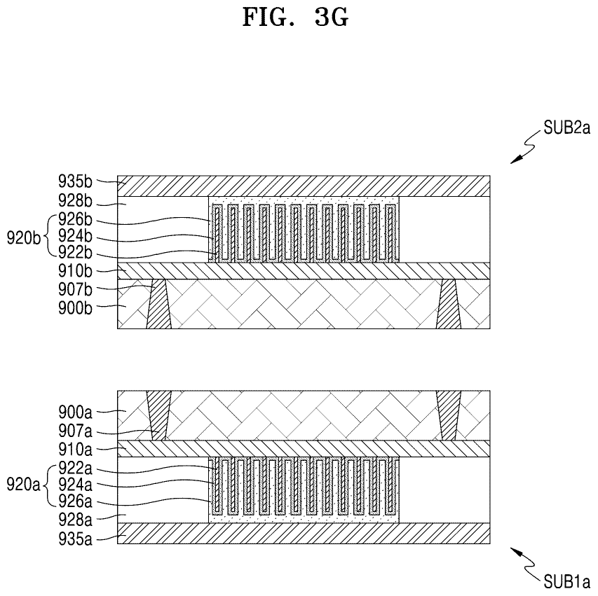

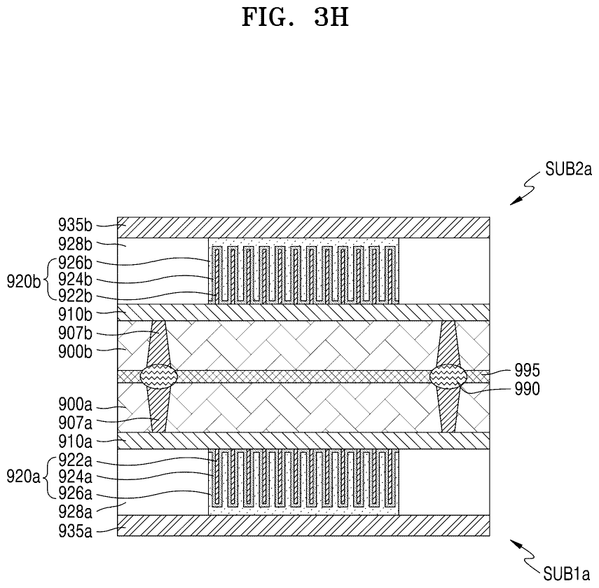

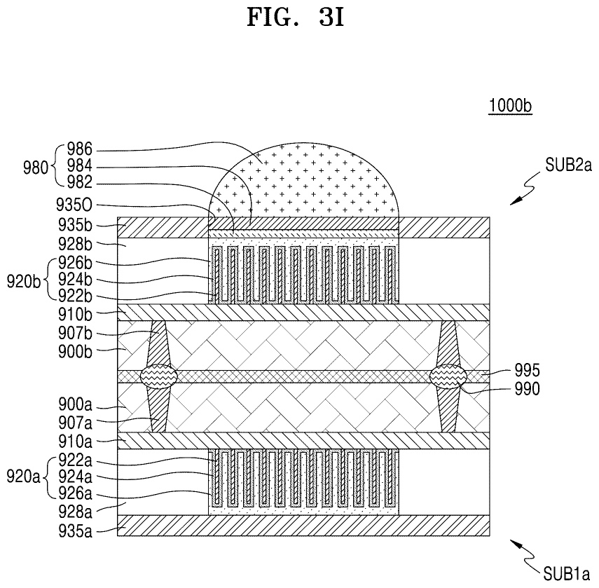

FIGS. 3A to 3I are cross-sectional views illustrating a method of manufacturing a capacitor structure 1000b and a capacitor structure 1000b manufactured by the method according to an embodiment.

Referring to FIG. 3A, a preliminary base substrate 900P is prepared. In some embodiments, the preliminary base substrate 900P may be a silicon wafer.

Referring to FIGS. 3A and 3B together, part of the preliminary base substrate 900P is removed to form a base substrate 900. For example, the base substrate 900 may be formed by grinding the preliminary base substrate 900P to reduce a thickness of the preliminary base substrate 900P.

Referring to FIG. 3C, a base conductive layer 910 is formed on the base substrate 900.

Referring to FIG. 3D, a sub-capacitor structure 920 and a mold layer 928 surrounding the sub-capacitor structure 920 are formed on the base conductive layer 910. The sub-capacitor structure 920 is connected to the base conductive layer 910 and may include a plurality of conductive pillars 922 which are spaced apart from one another, a capacitor dielectric layer 924 covering the base conductive layer 910 and each of the plurality of conductive pillars 922, and an upper electrode 926 covering the capacitor dielectric layer 924. The base conductive layer 910 and the plurality of conductive pillars 922 may perform a function of a lower electrode of the sub-capacitor structure 920 together and may be referred to as a lower electrode corresponding to the upper electrode 926 of the sub-capacitor structure 920. For example, the sub-capacitor structure 920 may include the lower electrode, the upper electrode 926, and the capacitor dielectric layer 924 disposed therebetween.

Referring to FIG. 3E, a protective layer 935 covering a top surface of the mold layer 928 and a top surface of the upper electrode 926 is formed. The protective layer 935 may include or may be formed of an insulating material.

Referring to FIG. 3F, a through via 907 is formed through the base substrate 900 to form a sub-structure SUBa. The through via 907 may extend from a bottom surface of the base substrate 900 to a top surface of the base substrate 900. The through via 907 may be electrically connected to the base conductive layer 910. In some embodiments, the through via 907 may pass through the base substrate 900 from the bottom surface of the base substrate 900 and then may extend to the base conductive layer 910. The through via 907 may be formed to have a tapered shape of which a horizontal width and a horizontal area decrease from the bottom surface of the base substrate 900 to the top surface of the base substrate 900. For example, the through via 907 may be formed to have a tapered shape of which a horizontal width and a horizontal area decrease away from the bottom surface of the base substrate 900. In other words, the horizontal width and the horizontal area of the tapered shape may increase toward the bottom surface of the base substrate 900.

Referring to FIG. 3G, a first sub-structure SUB1a and a second sub-structure SUB2a are prepared. The first sub-structure SUB1a may include a first base substrate 900a, a first sub-capacitor structure 920a including a first through via 907a, a first base conductive layer 910a, a plurality of first conductive pillars 922a, a first capacitor dielectric layer 924a, and a first upper electrode 926a, a first mold layer 928a, and a first protective layer 935a. The second sub-structure SUB2a may include a second base substrate 900b, a second sub-capacitor structure 920b including a second through via 907b, a second base conductive layer 910b, a plurality of second conductive pillars 922b, a second capacitor dielectric layer 924b, and a second upper electrode 926b, a second mold layer 928b, and a second protective layer 935b.

Each of the first sub-structure SUB1a and the second sub-structure SUB2a may be substantially the same as the sub-structure SUBa illustrated in FIG. 3F. Each of the first base substrate 900a and the second base substrate 900b may be substantially the same as the base substrate 900 illustrated in FIG. 3F. Each of the first through via 907a and the second through via 907b may be substantially the same as the through via 907 illustrated in FIG. 3F. Each of the first base conductive layer 910a and the second base conductive layer 910b may be substantially the same as the base conductive layer 910 illustrated in FIG. 3F. Each of the plurality of first conductive pillars 922a and the plurality of second conductive pillars 922b may be substantially the same as the plurality of conductive pillars 922 illustrated in FIG. 3F. Each of the first capacitor dielectric layer 924a and the second capacitor dielectric layer 924b may be substantially the same as the capacitor dielectric layer 924 illustrated in FIG. 3F. Each of the first upper electrode 926a and the second upper electrode 926b may be substantially the same as the upper electrode 926 illustrated in FIG. 3F. Each of the first sub-capacitor structure 920a and the second sub-capacitor structure 920b may be substantially the same as the sub-capacitor structure 920 illustrated in FIG. 3F. Each of the first mold layer 928a and the second mold layer 928b may be substantially the same as the mold layer 928 illustrated in FIG. 3F. Each of the first protective layer 935a and the second protective layer 935b may be substantially the same as the protective layer 935 illustrated in FIG. 3F.

For example, the first sub-structure SUB1a may be the sub-structure SUBa illustrated in FIG. 3F flipped upside down, and the second sub-structure SUB2a may be the sub-structure SUBa illustrated in FIG. 3F. The first sub-structure SUB1a and the second sub-structure SUB2a may be arranged so that the first base substrate 900a and the second base substrate 900b face each other, and the first through via 907a and the second through via 907b face each other.

Referring to FIG. 3H, the first through via 907a and the second through via 907b are connected to each other by a connection bump 990.

An insulating adhesive layer 995 may be interposed between the first sub-structure SUB1a and the second sub-structure SUB2a. The insulating adhesive layer 995 may surround the connection bump 990, and may fill a space between the first sub-structure SUB1a and the second sub-structure SUB2a, that is, between the first base substrate 900a and the second base substrate 900b.

Referring to FIG. 3I, after removing part of the second protective layer 935b to form a bump opening 935O, a bump structure 980 is formed on the second upper electrode 926b exposed through the bump opening 935O to form the capacitor structure 1000b. In some embodiments, the bump structure 980 may include a connection pad layer 982, a UBM layer 984 on the connection pad layer 982, and a conductive cap 986 on the UBM layer 984. However, the inventive concept is not limited thereto.

The capacitor structure 1000b according to an embodiment includes the first sub-capacitor structure 920a and the second sub-capacitor structure 920b electrically connected to each other through the first through via 907a and the second through via 907b. The first through via 907a and the second through via 907b may be electrically connected to each other through the connection bump 990. Each of the first through via 907a and the second through via 907b may have a tapered shape of which a horizontal width and a horizontal area increase toward the connection bump 990. In other words, the tapered shape may have the horizontal width and the horizontal area which decrease away from the connection bump 990. The first through via 907a and the second through via 907b may be symmetrical to each other in the vertical direction. The first through via 907a and the second through via 907b may be symmetrical to each other with respect to the connection bump 990.

The first sub-capacitor structure 920a and the second sub-capacitor structure 960b may overlap each other in the vertical direction. The first sub-capacitor structure 920a and the second sub-capacitor structure 920b may be symmetrical to each other in the vertical direction. The first base substrate 900a and the second base substrate 900b may be referred to as a base substrate, and the first through via 907a and the second through via 907b may be referred to as a through via. The through via may pass through the base substrate. The first sub-capacitor structure 920a and the second sub-capacitor structure 920b may be symmetrical to each other with respect to the first base substrate 900a and the second base substrate 900b, and the first through via 907a and the second through via 907b. That is, the first sub-capacitor structure 920a and the second sub-capacitor structure 920b may be symmetrical to each other with respect to the base substrate and the through via.

The capacitor structure 1000b according to an embodiment includes the first sub-capacitor structure 920a and the second sub-capacitor structure 920b connected to each other through the first through via 907a and the second through via 907b. Therefore, according to an electrical connection method between the first sub-capacitor structure 920a and the second sub-capacitor structure 920b, rated voltage characteristics of the capacitor structure 1000b may be improved or capacitance thereof may be increased.

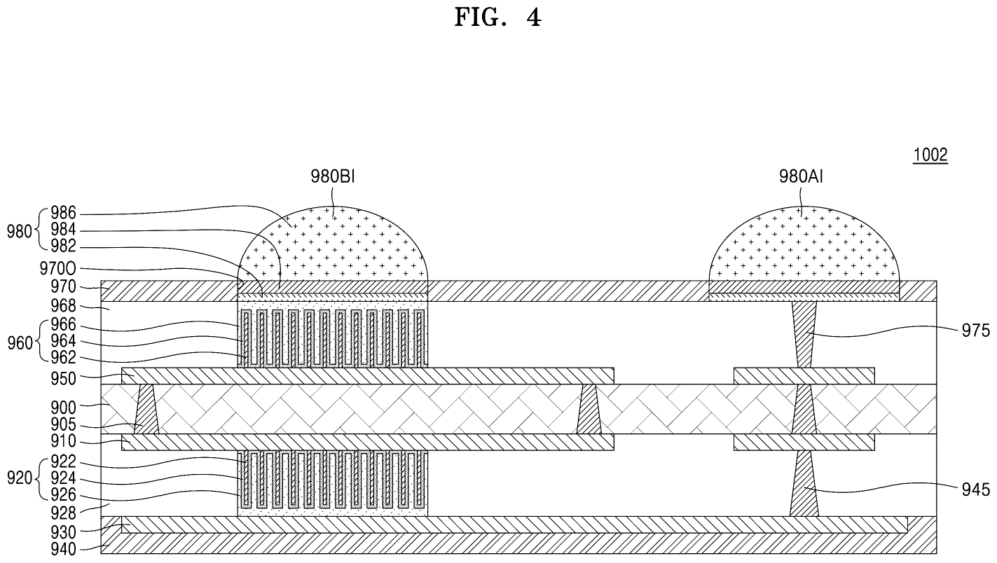

FIGS. 4 to 11 are cross-sectional views illustrating a capacitor structure 1002 according to an embodiment.

Referring to FIG. 4, the capacitor structure 1002 may have a structure similar to that of the capacitor structure 1000 illustrated in FIG. 1J. The capacitor structure 1002 includes a base substrate 900, a plurality of through vias 905 passing through the base substrate 900, a plurality of first base conductive layers 910 electrically connected to the plurality of through vias 905 under the base substrate 900, a first sub-capacitor structure 920 connected to at least one first base conductive layer 910 under at least one of the plurality of first base conductive layers 910, a first mold layer 928 surrounding the first sub-capacitor structure 920 under the base substrate 900 and the plurality of first base conductive layers 910, a connection conductive layer 930 under the first mold layer 928 and the first sub-capacitor structure 920, a first protective layer 940 covering a bottom surface of the first mold layer 928 and a bottom surface of the connection conductive layer 930, a plurality of second base conductive layers 950 electrically connected to the through via 905 on the base substrate 900, a second sub-capacitor structure 960 connected to at least one second base conductive layer 950 on at least one of the plurality of second base conductive layers 950, a second mold layer 968 surrounding the second sub-capacitor structure 960 on the base substrate 900 and the plurality of second base conductive layers 950, a second protective layer 970 covering a top surface of the second mold layer 968 and having a bump opening 970O, and at least two bump structures 980 arranged on the second upper electrode 966 exposed through the bump opening 970O.

The capacitor structure 1002 may further include a first connection via 945 extending through the first mold layer 928 and electrically connecting the connection conductive layer 930 to at least one other of the plurality of first base conductive layers 910 and a second connection via 975 extending through the second mold layer 968 and electrically connecting at least one other of the plurality of second base conductive layers 950 to one of the at least two bump structures 980. Each of the first connection via 945 and the second connection via 975 may have a tapered shape of which a horizontal width and a horizontal area increase away from the base substrate 900. The first connection via 945 and the second connection via 975 may be symmetrical to each other in the vertical direction. The first connection via 945 and the second connection via 975 may be symmetrical to each other with respect to the base substrate 900 and the through via 905.

The first sub-capacitor structure 920 and the second sub-capacitor structure 960 may be serially connected to each other. For example, a plurality of first conductive pillars 922 of the first sub-capacitor structure 920 may be electrically connected to a plurality of second conductive pillars 962 of the second sub-capacitor structure 960 through the first base conductive layer 910, the through via 905, and the second base conductive layer 950. A first upper electrode 926 of the first sub-capacitor structure 920 and a second upper electrode 966 of the second sub-capacitor structure 960 may be electrically connected to two bump structures 980, respectively. The two bump structures 980 may include a first bump structure 980A1 and a second bump structure 980B1. The first bump structure 980A1 may be electrically connected to the first upper electrode 926, and the second bump structure 980B1 may be electrically connected to the second upper electrode 966. For example, the first upper electrode 926 may be electrically connected to the first bump structure 980A1 through the connection conductive layer 930, the first connection via 945, the first base conductive layer 910, the through via 905, the second base conductive layer 950 and the second connection via 975. In some embodiments, the first bump structure 980A1, the second connection via 975, the second base conductive layer 950, and the through via 905, the first base conductive layer 910, and the first connection via 945 may overlap each other. For example, two sub-capacitor structures 920 and 960 may be connected with each other in series between the two bump structures 980A1 and 980B1 which serve as two terminals of the capacitor structure 1002.

Because the first sub-capacitor structure 920 and the second sub-capacitor structure 960 are serially connected to each other in the capacitor structure 1002, rated voltage characteristics of the capacitor structure 1002 may be improved.

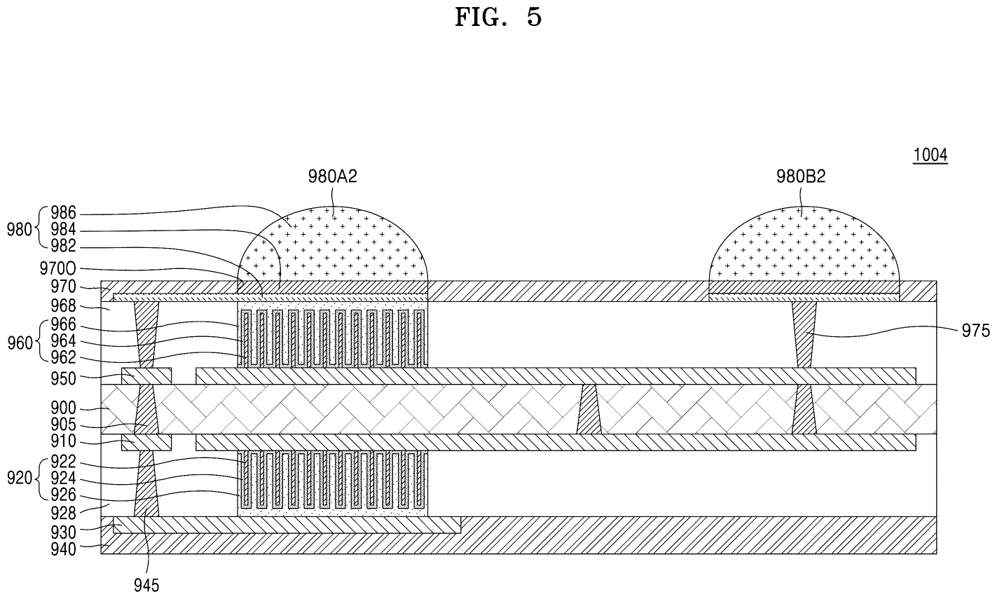

Referring to FIG. 5, because a capacitor structure 1004 may be the same as or similar to the capacitor structure 1002 illustrated in FIG. 4, redundant contents may be omitted.

The first sub-capacitor structure 920 and the second sub-capacitor structure 960 may be connected to each other in parallel. The plurality of first conductive pillars 922 of the first sub-capacitor structure 920 and the plurality of second conductive pillars 962 of the second sub-capacitor structure 960 may be electrically connected to one of at least two bump structures 980, and the first upper electrode 926 of the first sub-capacitor structure 920 and the second upper electrode 966 of the second sub-capacitor structure 960 may be electrically connected to another of the at least two bump structures 980.

For example, the plurality of first conductive pillars 922 of the first sub-capacitor structure 920 and the plurality of second conductive pillars 962 of the second sub-capacitor structure 960 may be electrically connected through the first base conductive layer 910, the through via 905, and the second base conductive layer 950, and may be electrically connected to one of the at least two bump structures 980 through the second connection via 975 electrically connected to the second base conductive layer 950. The first upper electrode 926 of the first sub-capacitor structure 920 and the second upper electrode 966 of the second sub-capacitor structure 960 may be electrically connected to another of the at least two bump structures 980 through the connection conductive layer 930, the first connection via 945, the first base conductive layer 910, the through via 905, the second base conductive layer 950, and the second connection via 975. The at least two bump structures 980 may include a first bump structure 980A2 which is electrically connected to the first upper electrode 926 and the second upper electrode 966, and a second bump structure 980B2 which is electrically connected to the plurality of first conductive pillars 922 and the plurality of second conductive pillars 962. For example, two sub-capacitor structures 920 and 960 may be connected with each other in parallel between two bump structures 980A2 and 980B2 which serve as two terminals of the capacitor structure 1004.

Because the first sub-capacitor structure 920 and the second sub-capacitor structure 960 are connected to each other in parallel in the capacitor structure 1004, capacitance of the capacitor structure 1004 may be increased.

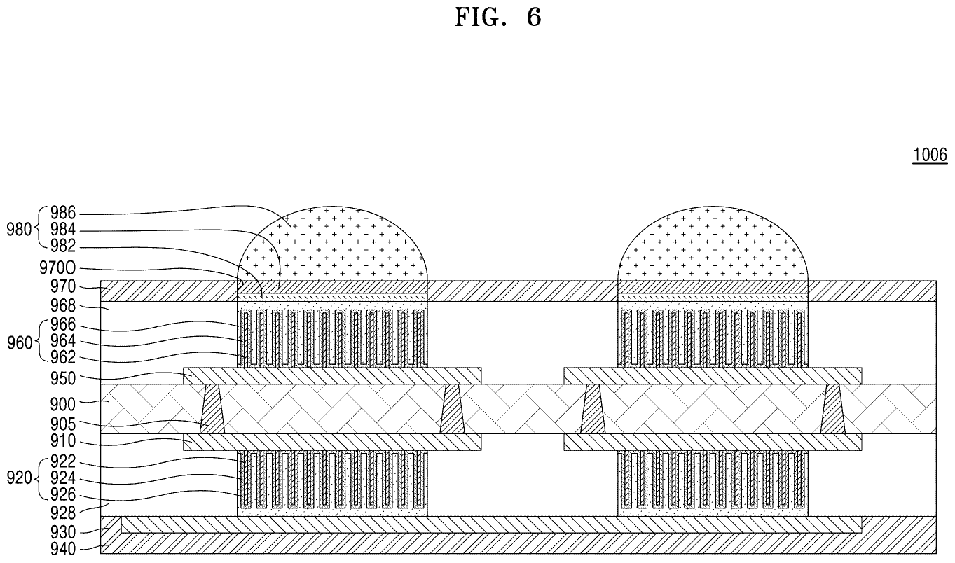

Referring to FIG. 6, because a capacitor structure 1006 may be the same as or similar to the capacitor structure 1002 illustrated in FIG. 4, redundant contents may be omitted. The capacitor structure 1006 may include a pair of first sub-capacitor structures 920 and a pair of second sub-capacitor structures 960. The pair of first sub-capacitor structures 920 and the pair of second sub-capacitor structures 960 may be connected in series. For example, one of the pair of first sub-capacitor structures 920, one of the pair of second sub-capacitor structures 960, the other of the pair of second sub-capacitor structures 960, and the other of the pair of first sub-capacitor structures 920 may be sequentially connected in series. One of the pair of second sub-capacitor structures 960 may be electrically connected to one of the two bump structures 980, and the other of the pair of second sub-capacitor structures 960 may be electrically connected to the other of the two bump structures 980. For example, four sub-capacitor structures may be connected with each other in series between the two bump structures 980. One of the two bump structures 980 may serve as a first terminal of the capacitor structure 1006 and the other may serve as a second terminal of the capacitor structure 1006.

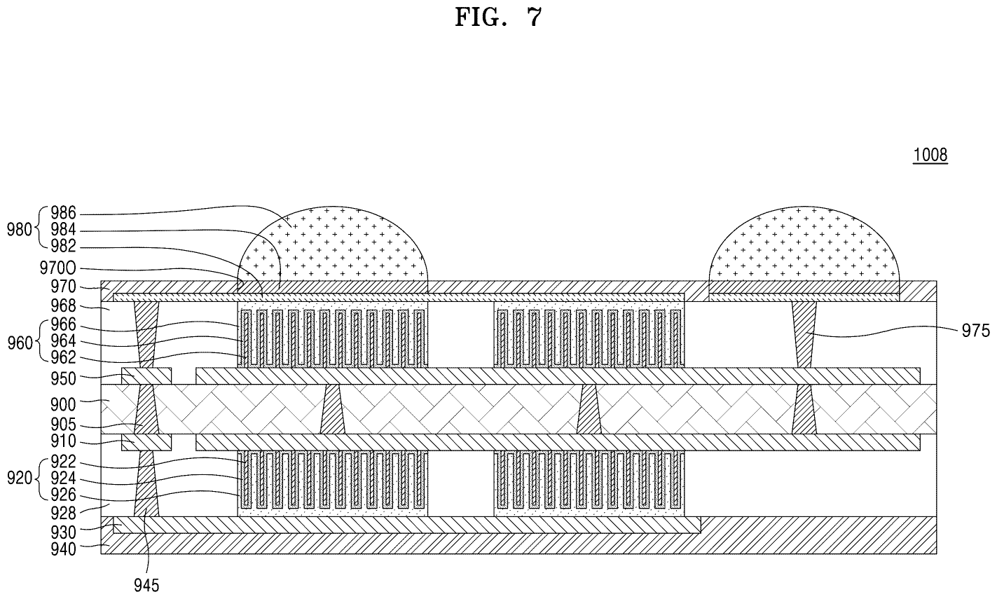

Referring to FIG. 7, because a capacitor structure 1008 may be the same as or similar to the capacitor structure 1006 illustrated in FIG. 6, redundant contents may be omitted. The capacitor structure 1008 may include a pair of first sub-capacitor structures 920 and a pair of second sub-capacitor structures 960. The pair of first sub-capacitor structures 920 and the pair of second sub-capacitor structures 960 may be connected in parallel. For example, a first upper electrode 926 of each of the pair of first sub-capacitor structures 920 and a second upper electrode 966 of each of the pair of second sub-capacitor structures 960 may be electrically connected in common to one of two bump structures 980, and a plurality of first conductive pillars 922 of each of the pair of first sub-capacitor structures 920 and a plurality of second conductive pillars 962 of each of the pair of second sub-capacitor structures 960 may be electrically connected in common to the other of the two bump structures 980. For example, four sub-capacitor structures may be connected with each other in parallel between the two bump structures 980. One of the two bump structures 980 may serve as a first terminal of the capacitor structure 1008 and the other may serve as a second terminal of the capacitor structure 1008.

Referring to FIGS. 4 to 7 together, the first sub-capacitor structure 920 and the second sub-capacitor structure 960 may be connected in series or in parallel according to a connection relationship between the first base conductive layer 910, the second base conductive layer 950, the through via 905, the connection conductive layer 930, the first connection via 945, and the second connection via 975, thereby improving rated voltage characteristics or increasing capacitance of the capacitor structures 1002, 1004, 1006, and 1008.

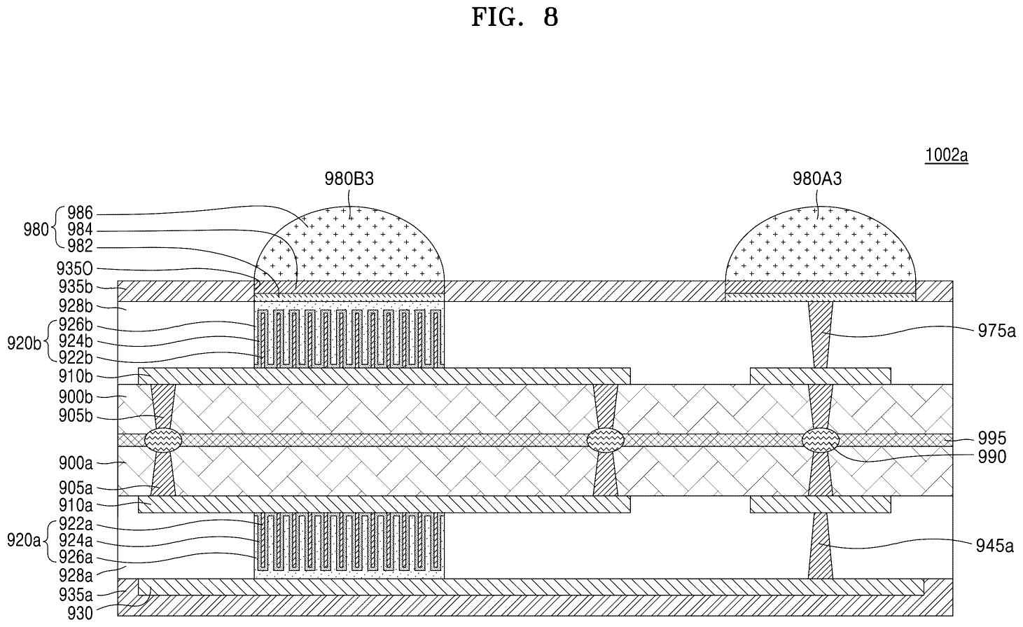

Referring to FIG. 8, a capacitor structure 1002a may have a structure similar to that of the capacitor structure 1000a illustrated in FIG. 2I. The capacitor structure 1002a includes a first base substrate 900a, a first through via 905a, a first base conductive layer 910a, a first sub-capacitor structure 920a, a first mold layer 928a, a first protective layer 935a, a second base substrate 900b, a second through via 905b, a second base conductive layer 910b, a second sub-capacitor structure 920b, a second mold layer 928b, a second protective layer 935b, a connection bump 990 connecting the first through via 905a to the second through via 905b, and an insulating adhesive layer 995 surrounding the connection bump 990 and filling a space between the first base substrate 900a and the second base substrate 900b.

The capacitor structure 1002a may further include a first connection via 945a passing through the first mold layer 928a and a second connection via 975a passing through the second mold layer 928b. The first connection via 945a and the second connection via 975a may be symmetrical to each other in the vertical direction.

The first sub-capacitor structure 920a and the second sub-capacitor structure 920b may be serially connected to each other. For example, a plurality of first conductive pillars 922a of the first sub-capacitor structure 920a may be electrically connected to a plurality of second conductive pillars 922b of the second sub-capacitor structure 920b through the first base conductive layer 910a, the first through via 905a, the connection bump 990, the second through via 905b, and the second base conductive layer 910b. A first upper electrode 926a of the first sub-capacitor structure 920a and a second upper electrode 926b of the second sub-capacitor structure 920b may be electrically connected to two bump structures 980, respectively. The two bump structures 980 may include a first bump structure 980A3 which is electrically connected to the first upper electrode 926a, and a second bump structure 980B3 which is electrically connected to the second upper electrode 926b. For example, the first upper electrode 926a may be electrically connected to the first bump structure 980A3 through the connection conductive layer 930, the first connection via 945a, the first base conductive layer 910a, the first through via 905a, the connection bump 990, the second through via 905b, the second base conductive layer 910b, and the second connection via 975a. The second upper electrode 926b may be electrically connected to the second bump structure 980B3. For example, two sub-capacitor structures 920a and 920b may be connected with each other in series between the two bump structures 980A3 and 980B3 which serve as two terminals of the capacitor structure 1002a.

Because the first sub-capacitor structure 920a and the second sub-capacitor structure 920b are serially connected to each other in the capacitor structure 1002a, rated voltage characteristics of the capacitor structure 1002a may be improved.

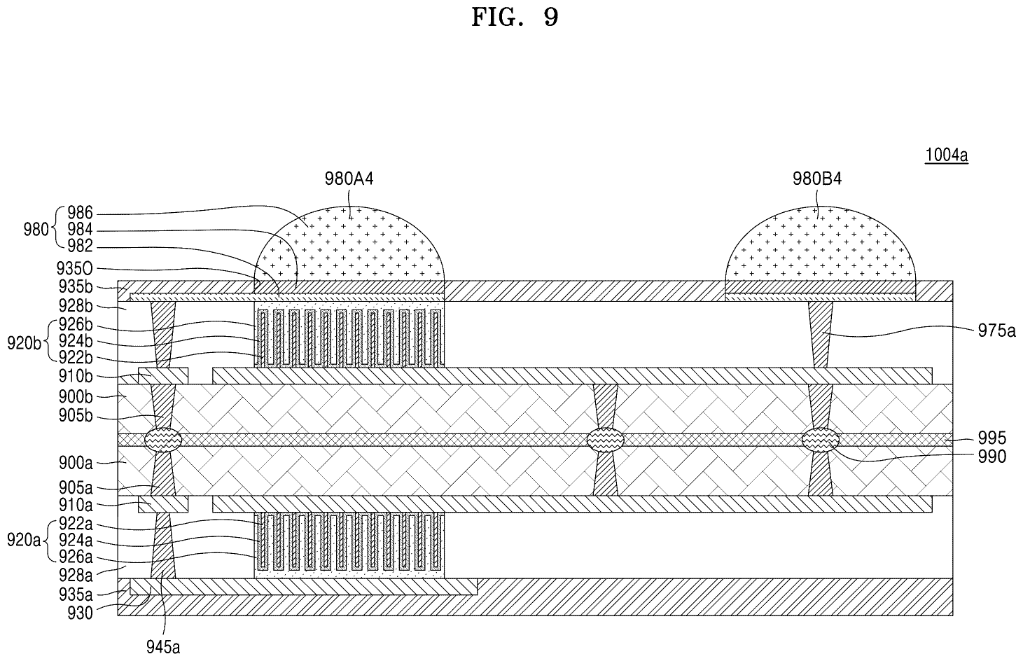

Referring to FIG. 9, because a capacitor structure 1004a may be the same as or similar to the capacitor structure 1002a illustrated in FIG. 8, redundant contents may be omitted.

A first sub-capacitor structure 920a and a second sub-capacitor structure 920b may be connected to each other in parallel. A plurality of first conductive pillars 922a of the first sub-capacitor structure 920a and a plurality of second conductive pillars 922b of the second sub-capacitor structure 920b may be electrically connected to one of two bump structures 980, and a first upper electrode 926a of the first sub-capacitor structure 920a and a second upper electrode 926b of the second sub-capacitor structure 920b may be electrically connected to the other of the two bump structures 980.

For example, the plurality of first conductive pillars 922a of the first sub-capacitor structure 920a and the plurality of second conductive pillars 922b of the second sub-capacitor structure 920b may be electrically connected through a first base conductive layer 910a, a first through via 905a, a connection bump 990, a second through via 905b, and a second base conductive layer 910b and may be electrically connected to one of the at least two bump structures 980 through a second connection via 975a electrically connected to the second base conductive layer 910b. The first upper electrode 926a of the first sub-capacitor structure 920a and the second upper electrode 926b of the second sub-capacitor structure 920b may be electrically connected to the other of the two bump structures 980 through a connection conductive layer 930, a first connection via 945a, a first base conductive layer 910a, a first through via 905a, a connection bump 990, a second through via 905b, a second base conductive layer 910b, and a second connection via 975a. The two bump structures 980 may include a first bump structure 980A4 which is electrically connected to the first upper electrode 926a and the second upper electrode 926b, and a second bump structure 980B4 which is electrically connected to the plurality of first conductive pillars 922a and the plurality of second conductive pillars 922b. For example, the two bump structures 980A4 and 980B4 may serve as a first terminal and a second terminal of the capacitor structure 1004a in which two sub-capacitor structures are connected with each other in parallel.

Because the first sub-capacitor structure 920a and the second sub-capacitor structure 920b are connected to each other in parallel in the capacitor structure 1004a, capacitance of the capacitor structure 1004a may be increased.

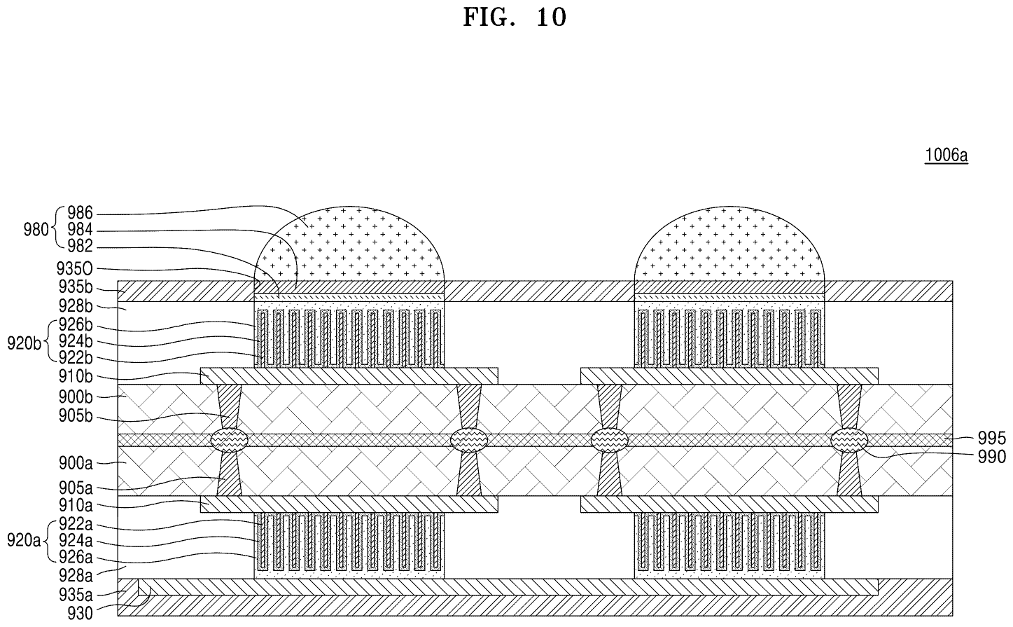

Referring to FIG. 10, because a capacitor structure 1006a may be the same as or similar to the capacitor structure 1002a illustrated in FIG. 8, redundant contents may be omitted. The capacitor structure 1006a may include a pair of first sub-capacitor structures 920a and a pair of second sub-capacitor structures 920b. The pair of first sub-capacitor structures 920a and the pair of second sub-capacitor structures 920b may be connected in series. For example, one of the pair of first sub-capacitor structures 920a, one of the pair of second sub-capacitor structures 920b, the other of the pair of second sub-capacitor structures 920b, and the other of the pair of first sub-capacitor structures 920a may be sequentially connected in series. One of the pair of first sub-capacitor structures 920a may be electrically connected to one of two bump structures 980, and the other of the pair of first sub-capacitor structures 920a may be electrically connected to the other of the two bump structures 980. For example, four sub-capacitors may be connected with each other in series between the two bump structures 980 which serve as two terminals of the capacitor structure 1006a.

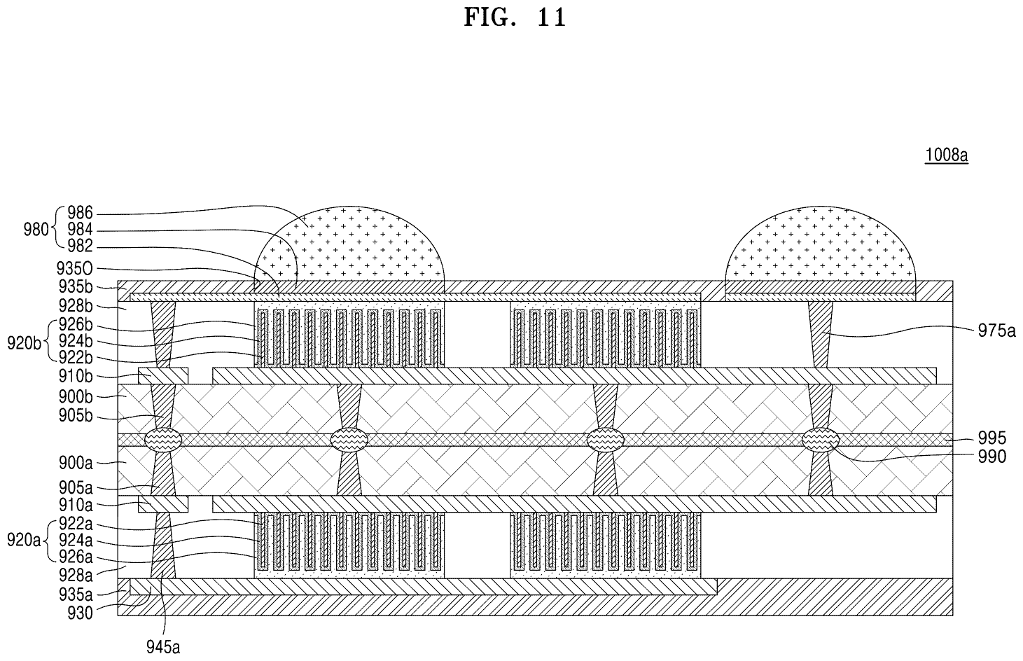

Referring to FIG. 11, because a capacitor structure 1008a may be the same as or similar to the capacitor structure 1006a illustrated in FIG. 10, redundant contents may be omitted. The capacitor structure 1008a may include a pair of first sub-capacitor structures 920a and a pair of second sub-capacitor structures 920b. The pair of first sub-capacitor structures 920a and the pair of second sub-capacitor structures 920b may be connected in parallel. For example, a first upper electrode 926a of each of the pair of first sub-capacitor structures 920a and a second upper electrode 926b of each of the pair of second sub-capacitor structures 920b may be electrically connected in common to one of two bump structures 980, and a plurality of first conductive pillars 922a of each of the pair of first sub-capacitor structures 920a and a plurality of second conductive pillars 922b of each of the pair of second sub-capacitor structures 920b may be electrically connected in common to the other of the two bump structures 980. For example, four sub-capacitor structures may be connected with each other in parallel between the two bump structures 980 which serve as two terminals of the capacitor structure 1008a.

Referring to FIGS. 8 to 11, the first sub-capacitor structure 920a and the second sub-capacitor structure 920b may be connected in series or parallel according to a connection relationship between the first base conductive layer 910a, the second base conductive layer 910b, the first through via 905a, the second through via 905b, the connection conductive layer 930, the first connection via 945a, and the second connection via 975a, thereby improving rated voltage characteristics or increasing capacitance of the capacitor structures 1002a, 1004a, 1006a, and 1008a.

In addition, although not shown, it may be apparent to those skilled in the art that the capacitor structure 1000b illustrated in FIG. 31 may also be modified by connecting the first sub-capacitor structure 920a to the second sub-capacitor structure 920b in series or parallel with reference to FIGS. 8 to 11.

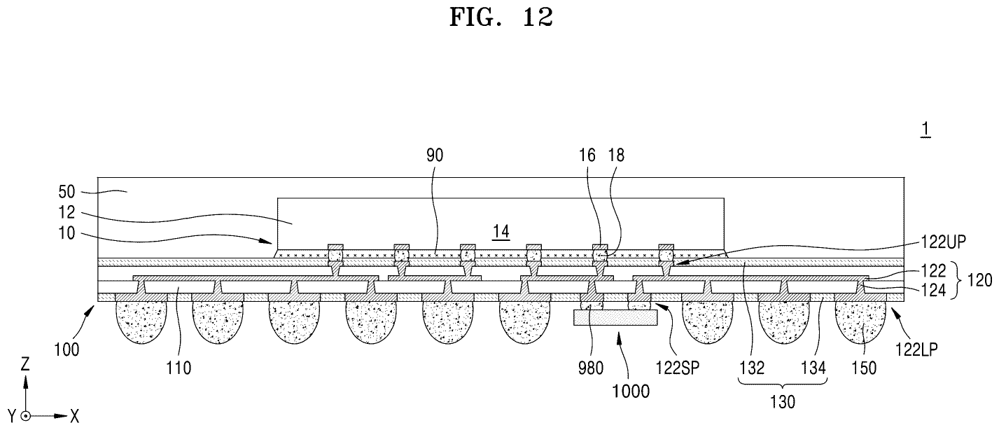

FIG. 12 is a cross-sectional view illustrating a semiconductor package 1 including a capacitor structure 1000 according to an embodiment.

Referring to FIG. 12, the semiconductor package 1 includes a package substrate 100, a semiconductor chip 10 attached to a top surface of the package substrate 100, the capacitor structure 1000 attached to a bottom surface of the package substrate 100, and an encapsulant 50 surrounding the semiconductor chip 10.

In some embodiments, the package substrate 100 may be a printed circuit board (PCB). For example, the package substrate 100 may be a double-sided PCB or a multi-layer PCB. The package substrate 100 may include a substrate base 110 (i.e., a first substrate) and a wiring structure 120. The wiring structure 120 may include a plurality of wiring patterns 122 arranged on top and bottom surfaces of the substrate base 110 or in the substrate base 110 and extending in the horizontal direction and a plurality of wiring vias 124 extend in the vertical direction through at least part of the substrate base 110 to electrically connect two wiring patterns 122 at different vertical levels among the plurality of wiring patterns 122. In some embodiments, the substrate base 110 may have a stacked structure of a plurality of base layers, and the plurality of wiring patterns 122 may be arranged on top and bottom surfaces of each of the plurality of base layers.

The package substrate 100 may further include a solder resist layer 130 covering top and bottom surfaces of the substrate base 110. The solder resist layer 130 may include a top surface solder resist layer 132 covering the top surface of the substrate base 110 and a bottom surface solder resist layer 134 covering the bottom surface of the substrate base 110. Among the wiring patterns 122 arranged on the top surface of the substrate base 110, parts exposed without being covered with the top surface solder resist layer 132 may be referred to as a plurality of top surface pads 122UP and, among the wiring patterns 122 arranged on the bottom surface of the substrate base 110, parts exposed without being covered with the bottom surface solder resist layer 134 may be referred to as a plurality of bottom surface connection pads 122LP and a plurality of passive element connection pads 122SP. A plurality of external connection terminals 150 may be attached to the plurality of bottom surface connection pads 122LP. In some embodiments, the plurality of external connection terminals 150 may be solder balls. Each of the plurality of bottom surface connection pads 122LP and the plurality of passive element connection pads 122SP may be referred to as a bottom surface pad.

The substrate base 110 may include or may be formed of at least one material selected from phenol resin, epoxy resin, and polyimide. The substrate base 110 may include or may be formed of, for example, at least one material selected from frame retardant (FR) 4, tetrafunctional epoxy, polyphenylene ether, epoxy/polyphenylene oxide, bismaleimide triazine (BT), thermount, cyanate ester, polyimide, and liquid crystal polymer.

The wiring structure 120 may include or may be formed of Cu. For example, each of the plurality of wiring patterns 122 and the plurality of wiring vias 124 may include electrolytically deposited (ED) copper foil, rolled-annealed (RA) copper foil, ultra-thin copper foil, sputtered copper, or a copper alloy.

The semiconductor chip 10 may include a semiconductor substrate 12 having active and inactive surfaces opposite to each other, a semiconductor device 14 formed on the active surface of the semiconductor substrate 12, and a plurality of chip pads 16 arranged on a first surface of the semiconductor chip 10. In the current specification, the first surface of the semiconductor chip 10 and a second surface of the semiconductor chip 10 are opposite to each other, and the second surface of the semiconductor chip 10 refers to the inactive surface of the semiconductor substrate 12. Because the active surface of the semiconductor substrate 12 is very close to the first surface of the semiconductor chip 10, illustration in which the active surface of the semiconductor substrate 12 and the first surface of the semiconductor chip 10 are divided is omitted. In some embodiments, the active surface of the semiconductor substrate 12 may correspond to the first surface of the semiconductor chip 10.

In some embodiments, the semiconductor chip 10 has a face-down arrangement in which the first surface faces the package substrate 100, and may be attached to the top surface of the package substrate 100. In this case, the first surface of the semiconductor chip 10 may be referred to as a bottom surface of the semiconductor chip 10, and the second surface of the semiconductor chip 10 may be referred to as a top surface of the semiconductor chip 10. For example, a plurality of chip connection members 18 may be interposed between the plurality of chip pads 16 of the semiconductor chip 10 and the plurality of top surface pads 122UP of the package substrate 100. For example, the plurality of chip connection members 18 may be solder balls or micro-bumps. The semiconductor chip 10 and the package substrate 100 may be electrically connected to each other through the plurality of chip connection members 18. In some embodiments, an underfill layer 90 may be interposed between the bottom surface of the semiconductor chip 10 and the top surface of the package substrate 100. The underfill layer 90 may surround the plurality of chip connection members 18. The underfill layer 90 may include or may be formed of, for example, a resin material formed by a capillary underfill method.

Unless otherwise specified in the current specification, the top surface refers to a surface facing upward in the drawings, and the bottom surface refers to a surface facing downward in the drawings.

The semiconductor substrate 12 may include or may be formed of, for example, a semiconductor material such as silicon (Si) and germanium (Ge). In some embodiments, the semiconductor substrate 12 may include or may be formed of a compound semiconductor material such as silicon carbide (SiC), gallium arsenide (GaAs), indium arsenide (InAs), and indium phosphide (InP). The semiconductor substrate 12 may include a conductive region, for example, a well doped with impurities. The semiconductor substrate 12 may have various device isolation structures such as a shallow trench isolation (STI) structure.

The semiconductor device 14 including a plurality of various types of individual devices may be formed on the active surface of the semiconductor substrate 12. The plurality of individual devices may include various microelectronic devices, for example, a metal-oxide-semiconductor field effect transistor (MOSFET) such as a complementary metal-insulator-semiconductor (CMOS) transistor, a system large scale integration (LSI), an active element, and a passive element. The plurality of individual devices may be electrically connected to the conductive region of the semiconductor substrate 12. The semiconductor device 14 may further include a conductive wire or a conductive plug electrically connecting at least two of the plurality of individual devices or the plurality of individual devices to the conductive region of the semiconductor substrate 12. In addition, each of the plurality of individual devices may be electrically separated from other neighboring individual devices by an insulating layer.

In some embodiments, the semiconductor chip 10 may be a central processing unit (CPU) chip, a graphics processing unit (GPU) chip, or an application processor (AP) chip. In other embodiments, the semiconductor chip 10 may be, for example, a memory semiconductor chip. The memory semiconductor chip may be, for example, a non-volatile memory semiconductor chip such as flash memory, phase-change random access memory (PRAM), magnetoresistive random access memory (MRAM), ferroelectric random access memory (FeRAM), or resistive random access memory (RRAM). The flash memory may be, for example, NAND flash memory or V-NAND flash memory. In some embodiments, the semiconductor chip 10 may be a volatile memory semiconductor chip such as dynamic random access memory (DRAM) or static random access memory (SRAM).

The encapsulant 50 may surround the semiconductor chip 10 on the top surface of the package substrate 100. The encapsulant 50 may cover at least part of the top surface of the package substrate 100. In some embodiments, the encapsulant 50 may completely cover the top surface of the package substrate 100. In some embodiments, the encapsulant 50 may cover both the top and side surfaces of the semiconductor chip 10. In some embodiments, the encapsulant 50 may cover the side surfaces of the semiconductor chip 10, but may expose the top surface of the semiconductor chip 10 without covering the top surface of the semiconductor chip 10. The encapsulant 50 may fill a space between the bottom surface of the semiconductor chip 10 and the top surface of the package substrate 100 and may surround the plurality of chip connection members 18. For example, the encapsulant 50 may be a molding member including an epoxy mold compound (EMC).

The capacitor structure 1000 may be a passive element. For example, the capacitor structure 1000 may be a silicon capacitor, a ceramic capacitor, a low inductance ceramic capacitor (LICC), or an intermediate storage capacitor (ISC). Although it is illustrated in FIG. 12 that the semiconductor package 1 includes the capacitor structure 1000 illustrated in FIG. 1J, the inventive concept is not limited thereto. For example, instead of the capacitor structure 1000 illustrated in FIG. 1J, the semiconductor package 1 may include any one of the capacitor structure 1000a illustrated in FIG. 2I, the capacitor structure 1000b illustrated in FIG. 3I, the capacitor structure 1002 illustrated in FIG. 4, the capacitor structure 1004 illustrated in FIG. 5, the capacitor structure 1006 illustrated in FIG. 6, the capacitor structure 1008 illustrated in FIG. 7, the capacitor structure 1002a illustrated in FIG. 8, the capacitor structure 1004a illustrated in FIG. 9, the capacitor structure 1006a illustrated in FIG. 10, and the capacitor structure 1008a illustrated in FIG. 11. The base substrate of the capacitor structure 1000 may be referred to as a second substrate.

The capacitor structure 1000 may be connected to the plurality of passive element connection pads 122SP of the package substrate 100 through a plurality of bump structures 980. For example, the capacitor structure 1000 may include two bump structures 980.

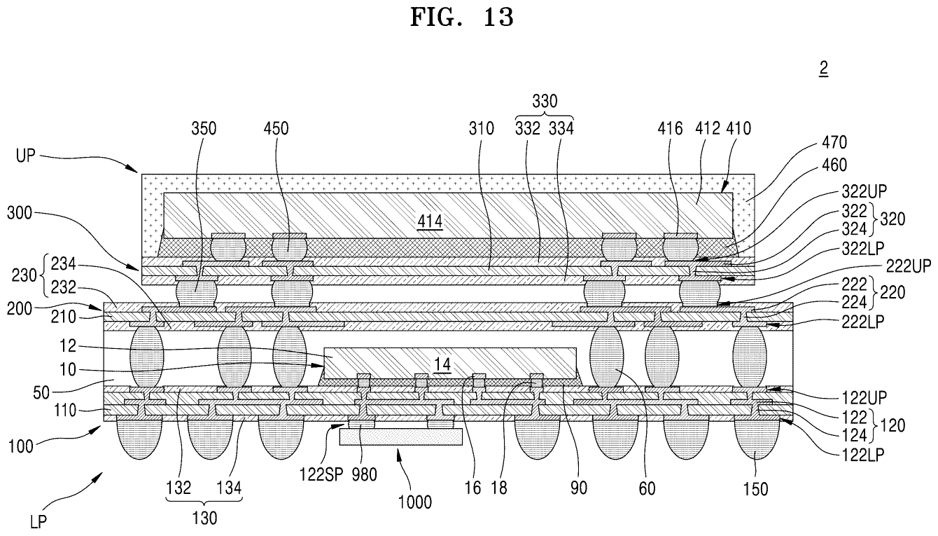

FIG. 13 is a cross-sectional view illustrating a semiconductor package 2 including a capacitor structure 1000 according to an embodiment.

Referring to FIG. 13, the semiconductor package 2 may be a package on package (POP) type semiconductor package in which an upper package UP is attached onto a lower package LP.

The lower package LP includes a first package substrate 100, a first semiconductor chip 10 attached onto the first package substrate 100, a second package substrate 200 covering the first semiconductor chip 10, and the capacitor structure 1000 attached to a bottom surface of the first package substrate 100. Because the first package substrate 100 and the first semiconductor chip 10 are substantially the same as the package substrate 100 and the semiconductor chip 10 illustrated in FIG. 12, respectively, redundant contents may be omitted.

The first package substrate 100 may include a first substrate base 110 and a first wiring structure 120. The first wiring structure 120 may include a plurality of first wiring patterns 122 and a plurality of first wiring vias 124. The first package substrate 100 may further include a first solder resist layer 130. The first solder resist layer 130 may include a first top surface solder resist layer 132 and a first bottom surface solder resist layer 134. Among the first wiring patterns 122 arranged on the top surface of the first substrate base 110, parts exposed without being covered with the first top surface solder resist layer 132 may be referred to as a plurality of first top surface pads 122UP and, among the first wiring patterns 122 arranged on the bottom surface of the first substrate base 110, parts exposed without being covered with the first bottom surface solder resist layer 134 may be referred to as a plurality of bottom surface connection pads 122LP and a plurality of passive element connection pads 122SP. Each of the plurality of bottom surface connection pads 122LP and the plurality of passive element connection pads 122SP may be referred to as a first bottom surface pad.

The first semiconductor chip 10 may include a first semiconductor substrate 12 having active and inactive surfaces opposite to each other, a first semiconductor device 14 formed on the active surface of the first semiconductor substrate 12, and a plurality of first chip pads 16 arranged on a first surface of the first semiconductor chip 10. The first semiconductor chip 10, the first semiconductor substrate 12, the first semiconductor device 14, the first chip pad 16, the first chip connection member 18, and the first underfill layer 90 illustrated in FIG. 12 may be substantially the same as the semiconductor chip 10, the semiconductor substrate 12, the semiconductor device 14, the chip pad 16, the chip connection member 18, and the underfill layer 90, respectively.

In some embodiments, the first package substrate 100 may be a PCB. In some embodiments, the first package substrate 100 may be a redistribution structure including a redistribution line, a redistribution via, and a redistribution insulating layer surrounding the redistribution line and the redistribution via.

The second package substrate 200 may cover the first semiconductor chip 10 on the first package substrate 100. The second package substrate 200 may be spaced apart from the first semiconductor chip 10 in the vertical direction. In some embodiments, the second package substrate 200 may be a PCB. For example, the second package substrate 200 may be a multi-layer PCB. In some embodiments, the second package substrate 200 may be a redistribution structure including a redistribution line, a redistribution via, and a redistribution insulating layer surrounding the redistribution line and the redistribution via.

The second package substrate 200 may include a second substrate base 210 and a second wiring structure 220 including a plurality of second wiring patterns 222 arranged on top and bottom surfaces of the second substrate base 210 and a plurality of second substrate vias 224 passing through at least part of the second substrate base 210. In some embodiments, in the second package substrate 200, the plurality of second substrate bases 210 may form a stacked structure, and the plurality of second wiring patterns 222 may be arranged on top and/or bottom surfaces of each of the plurality of second substrate bases 210. Some of the plurality of second wiring patterns 222 may be second top surface pads 222UP arranged on a top surface of the second package substrate 200, and others of the plurality of second wiring patterns 222 may be second bottom surface pads 222LP arranged on a bottom surface of the second package substrate 200. Among the plurality of second top surface pads 222UP and the plurality of second bottom surface pads 222LP, the second top surface pads 222UP may be electrically connected to the second bottom surface pads 222LP through some of the plurality of second substrate vias 224 or through some of the plurality of second wiring patterns 222 and some of the plurality of second substrate vias 224.

In some embodiments, the second package substrate 200 may further include a second solder resist layer 230 covering the top and bottom surfaces of the second substrate base 210. The second solder resist layer 230 may include a second top surface solder resist layer 232 exposing the plurality of second top surface pads 222UP and covering the top surface of the second substrate base 210 and a second bottom surface solder resist layer 234 exposing the plurality of second bottom surface pads 222LP and covering the bottom surface of the second substrate base 210.

Because the second package substrate 200, the second substrate base 210, the second wiring structure 220, and the second solder resist layer 230 are substantially similar to the first package substrate 100, the first substrate base 110, the first wiring structure 120, and the first solder resist layer 130, respectively, redundant descriptions are omitted.

In some embodiments, horizontal width and horizontal area of the first package substrate 100 may be the same as horizontal width and horizontal area of the second package substrate 200.

In some embodiments, the number of wiring layers of the second package substrate 200 may be less than the number of wiring layers of the first package substrate 100. In the current specification, the wiring layer refers to a place having circuit wiring forming an electrical path on the same plane. Although it is illustrated in FIG. 13 that the first package substrate 100 has three wiring layers and the second package substrate 200 has two wiring layers, the inventive concept is not limited thereto.

The encapsulant 50 may fill a space between the first package substrate 100 and the second package substrate 200 and may surround the first semiconductor chip 10. The encapsulant 50 may cover a top surface of the first package substrate 100 and the bottom surface of the second package substrate 200. In some embodiments, the encapsulant 50 may fill a space between a top surface of the first semiconductor chip 10 and the bottom surface of the second package substrate 200 so that the first semiconductor chip 10 and the second package substrate 200 are spaced apart from each other. In some embodiments, edges of the first package substrate 100, the second package substrate 200, and the encapsulant 50 may be aligned with one another in the vertical direction.

A plurality of solder balls 60 may be interposed between the first package substrate 100 and the second package substrate 200. In some embodiments, the encapsulant 50 may surround each of the plurality of solder balls 60. The plurality of solder balls 60 may be spaced apart from the semiconductor chip 10 in the horizontal direction. The plurality of solder balls 60 may connect a plurality of first top surface pads 122UP to a plurality of second bottom surface pads 222LP. Top surfaces of the plurality of solder balls 60 may contact the plurality of second bottom surface pads 222LP, and bottom surfaces of the plurality of solder balls 60 may contact the plurality of first top surface pads 122UP. The plurality of solder balls 60 may include or may be conductive solders. For example, the plurality of solder balls 60 may include or may be formed of at least one material selected from Sn, bismuth (Bi), Ag, and zinc (Zn). A vertical height of each of the plurality of solder balls 60 may be about 100 μm to about 440 μm.

An upper package UP may include a third package substrate 300, a second semiconductor chip 410 attached to a top surface of the third package substrate 300, a second encapsulant 470 surrounding the second semiconductor chip 410, and a plurality of package connection members 350 attached to a bottom surface of the third package substrate 300. The plurality of package connection members 350 may be respectively connected to the plurality of second top surface pads 222UP.

The third package substrate 300 may include a third substrate base 310 and a third wiring structure 320 including a plurality of third wiring patterns 322 arranged on top and bottom surfaces of the third substrate base 310 and a plurality of third substrate vias 324 passing through at least part of the third substrate base 310. In some embodiments, in the third package substrate 300, the third substrate base 310 may include a plurality of substrate bases which are formed in a stacked structure, and the plurality of third wiring patterns 322 may be arranged on top and/or bottom surfaces of each of the plurality of substrate bases in the third substrate base 310. Some of the plurality of third wiring patterns 322 may be third top surface pads 322UP arranged on the top surface of the third package substrate 300, and others of the plurality of third wiring patterns 322 may be third bottom surface pads 322LP arranged on a bottom surface of the third package substrate 300. Among the plurality of third top surface pads 322UP and the plurality of third bottom surface pads 322LP, the third top surface pads 322UP may be electrically connected to the third bottom surface pads 322LP through some of the plurality of third substrate vias 324 or through some of the plurality of third wiring patterns 322 and some of the plurality of third substrate vias 324.

In some embodiments, the third package substrate 300 may further include a third solder resist layer 330 covering the top and bottom surfaces of the third substrate base 310. The third solder resist layer 330 may include a third top surface solder resist layer 332 exposing the plurality of third top surface pads 322UP and covering the top surface of the third substrate base 310 and a third bottom surface solder resist layer 334 exposing the plurality of third bottom surface pads 322LP and covering the bottom surface of the third substrate base 310.

The plurality of package connection members 350 may be attached to the plurality of third bottom surface pads 322LP. For example, the plurality of package connection member 350 may be interposed between the plurality of second top surface pads 222UP and the plurality of third bottom surface pads 322LP.

Because the third package substrate 300, the third substrate base 310, the third wiring structure 320, and the third solder resist layer 330 are substantially similar to the first package substrate 100, the first substrate base 110, the first wiring structure 120, and the first solder resist layer 130, respectively, redundant descriptions are omitted.

The second semiconductor chip 410 may include a second semiconductor substrate 412 having active and inactive surfaces opposite to each other, a second semiconductor device 414 formed on the active surface of the second semiconductor substrate 412, and a plurality of second chip pads 416 arranged on a first surface of the second semiconductor chip 410. The second semiconductor chip 410 and the third package substrate 300 may be electrically connected through a plurality of second chip connection members 450 connecting the plurality of second chip pads 416 to the plurality of third top surface pads 322UP. Because the second semiconductor chip 410 is substantially similar to the first semiconductor chip 10, redunant descriptions may be omitted. In some embodiments, the first semiconductor chip 10 may be a CPU chip, a GPU chip, or an AP chip, and the second semiconductor chip 410 may be a memory semiconductor chip.

In some embodiments, a second underfill layer 460 surrounding each of the plurality of second chip connection members 450 may be interposed between a second surface, that is, a bottom surface of the second semiconductor chip 410 and the third package substrate 300. In some embodiments, the second encapsulant 470 may cover the top surface of the third package substrate 300 and may surround the second semiconductor chip 410 and the second underfill layer 460.

Although it is illustrated in FIG. 13 that the second semiconductor chip 410 has a face-up arrangement and is attached to the top surface of the third package substrate 300, the inventive concept is not limited thereto. For example, the second semiconductor chip 410 may have a face-down arrangement and may be attached to the top surface of the third package substrate 300.

The capacitor structure 1000 may be connected to the plurality of passive element connection pads 122SP of the package substrate 100 through a plurality of bump structures 980. Although it is illustrated in FIG. 13 that the semiconductor package 2 includes the capacitor structure 1000 illustrated in FIG. 1J, the inventive concept is not limited thereto. For example, instead of the capacitor structure 1000 illustrated in FIG. 1J, the semiconductor package 2 may include any one of the capacitor structure 1000a illustrated in FIG. 2I, the capacitor structure 1000b illustrated in FIG. 3I, the capacitor structure 1002 illustrated in FIG. 4, the capacitor structure 1004 illustrated in FIG. 5, the capacitor structure 1006 illustrated in FIG. 6, the capacitor structure 1008 illustrated in FIG. 7, the capacitor structure 1002a illustrated in FIG. 8, the capacitor structure 1004a illustrated in FIG. 9, the capacitor structure 1006a illustrated in FIG. 10, and the capacitor structure 1008a illustrated in FIG. 11.

While the inventive concept has been particularly shown and described with reference to embodiments thereof, it will be understood that various changes in form and details may be made therein without departing from the spirit and scope of the following claims.

What is claimed is:

1. A capacitor structure comprising:
a base substrate;
a through via extending in a vertical direction from a top surface of the base substrate to a bottom surface of the base substrate, wherein the vertical direction is perpendicular to the top surface of the base substrate;
a first sub-capacitor structure disposed on the bottom surface of the base substrate and including a first lower electrode electrically connected to a first end of the through via, a first upper electrode, and a first capacitor dielectric layer between the first lower electrode and the first upper electrode, wherein the first end of the through via is exposed at the bottom surface of the base substrate; and
a second sub-capacitor structure disposed on the top surface of the base substrate and including a second lower electrode electrically connected to a second end, opposite to the first end, of the through via, a second upper electrode, and a second capacitor dielectric layer between the second lower electrode and the second upper electrode on the top surface of the base substrate,
wherein the second end of the through via is exposed at the top surface of the base substrate, and
wherein the base substrate is interposed between the first sub-capacitor structure and the second sub-capacitor structure.

2. The capacitor structure of claim 1,
wherein the first sub-capacitor structure and the second sub-capacitor structure are symmetrical to each other in the vertical direction.

3. The capacitor structure of claim 1, further comprising:
a bump structure arranged on the second upper electrode and electrically connected to the second upper electrode.

4. The capacitor structure of claim 3,
wherein the through via has a tapered shape of a which horizontal width increases from the top surface of the base substrate to the bottom surface of the base substrate.

5. The capacitor structure of claim 3, further comprising:
a connection bump,
wherein the base substrate comprises:
a first base substrate; and
a second base substrate arranged on the first base substrate,
wherein the through via comprises:
a first through via extending through the first base substrate; and
a second through via extending through the second base substrate,
wherein the connection bump connects the first through via to the second through via, and
wherein the first through via and the second through via are symmetrical to each other with respect to the connection bump.

6. The capacitor structure of claim 5,
wherein each of the first through via and the second through via has a tapered shape of which a horizontal width decreases toward the connection bump.

7. The capacitor structure of claim 5,
wherein each of the first through via and the second through via has a tapered shape of which a horizontal width increases toward the connection bump.

8. The capacitor structure of claim 1,
wherein the first lower electrode comprises:
a first base conductive layer; and
a plurality of first conductive pillars connected to a bottom surface of the first base conductive layer and spaced apart from one another in a horizontal direction which is parallel to the top surface of the base substrate, and
wherein the second lower electrode comprises:
a second base conductive layer; and
a plurality of second conductive pillars connected to a top surface of the second base conductive layer and spaced apart from one another in the horizontal direction.

9. The capacitor structure of claim 8,
wherein the first end of the through via contacts a top surface of the first base conductive layer, and the second end of the through via contacts a bottom surface of the second base conductive layer.

10. A capacitor structure comprising:
a base substrate;
a first sub-capacitor structure disposed on a bottom surface of the base substrate and including a first lower electrode, a first upper electrode, and a first capacitor dielectric layer between the first lower electrode and the first upper electrode;
a first mold layer disposed on the bottom surface of the base substrate and surrounding the first sub-capacitor structure;
a second sub-capacitor structure disposed on a top surface of the base substrate and including a second lower electrode, a second upper electrode, and a second capacitor dielectric layer between the second lower electrode and the second upper electrode;
a second mold layer disposed on the top surface of the base substrate and surrounding the second sub-capacitor structure, wherein the base substrate is interposed between the first sub-capacitor structure and the second sub-capacitor structure and between the first mold layer and the second mold layer;
at least two through vias extending from the top surface of the base substrate to the bottom surface of the base substrate in a vertical direction which is perpendicular to the top surface of the base substrate;
a first bump structure arranged on the second upper electrode and electrically connected to the second upper electrode; and
a second bump structure arranged on the second mold layer,
wherein the at least two through vias include a first through via electrically connecting the first lower electrode to the second lower electrode.

11. The capacitor structure of claim 10,
wherein the second bump structure is electrically connected to the first upper electrode.

12. The capacitor structure of claim 11, further comprising:
a connection conductive layer disposed under the first upper electrode and electrically connected to the first upper electrode;
a first connection via passing through the first mold layer; and
a second connection via passing through the second mold layer,
wherein the first upper electrode is electrically connected to the second bump structure through the connection conductive layer, the first connection via, a second through via of the at least two through vias, and the second connection via.

13. The capacitor structure of claim 10,
wherein the second bump structure is electrically connected to the first lower electrode and the second lower electrode.

14. The capacitor structure of claim 13, further comprising:
a connection conductive layer disposed under the first upper electrode and electrically connected to the first upper electrode;
a first connection via passing through the first mold layer; and
at least two second connection vias passing through the second mold layer,
wherein the first upper electrode is electrically connected to the first bump structure through the connection conductive layer, the first connection via, a second through via of the at least two through vias, and one of the at least two second connection vias.

15. The capacitor structure of claim 14,
wherein the first lower electrode and the second lower electrode are electrically connected to the second bump structure through another second connection via of the at least two second connection vias.

16. The capacitor structure of claim 10,
wherein each of the at least two through vias has a tapered shape of which a horizontal width increases from the top surface of the base substrate to the bottom surface of the base substrate.

17. The capacitor structure of claim 10, further comprising:
a connection bump
wherein the base substrate comprises:
a first base substrate; and
a second base substrate arranged on the first base substrate,
wherein the through via comprises:
a first through via extending through the first base substrate; and
a second through via extending through the second base substrate,
wherein the connection bump connects the first through via to the second through via, and
wherein the first through via and the second through via have tapered shapes that are symmetrical to each other with respect to the connection bump.

18. A semiconductor package comprising:
a package substrate including:
a first substrate,
a plurality of top surface pads arranged on a top surface of the first substrate, and
a plurality of bottom surface connection pads and at least two passive element connection pads arranged on a bottom surface of the first substrate;
a semiconductor chip attached to the top surface of the first substrate and electrically connected to the package substrate through the plurality of top surface pads;
an encapsulant disposed on the top surface of the first substrate and surrounding the semiconductor chip;
a plurality of external connection terminals attached to the plurality of bottom surface connection pads; and
a capacitor structure attached to the bottom surface of the first substrate,
wherein the capacitor structure comprises:
a second substrate;
a first sub-capacitor structure including a first base conductive layer, a plurality of first conductive pillars connected to a bottom surface of the first base conductive layer and spaced apart from one another in a horizontal direction which is parallel to a top surface of the second substrate, a first capacitor dielectric layer covering the first base conductive layer and each of the plurality of first conductive pillars, and a first upper electrode covering the first capacitor dielectric layer, which are sequentially arranged under a bottom surface of the second substrate;
a second sub-capacitor structure including a second base conductive layer sequentially arranged on the top surface of the second substrate, a plurality of second conductive pillars connected to a top surface of the second base conductive layer and spaced apart from one another in the horizontal direction, a second capacitor dielectric layer covering the second base conductive layer and each of the plurality of second conductive pillars, and a second upper electrode covering the second capacitor dielectric layer;
a through via extending from the top surface of the second substrate to the bottom surface of the second substrate in a vertical direction which is perpendicular to the top surface of the second substrate and electrically connecting the first base conductive layer to the second base conductive layer; and
at least two bump structures attached to the at least two passive element connection pads,
wherein one of the at least two bump structures is arranged on the second upper electrode to be electrically connected to the second upper electrode, and
wherein the first sub-capacitor structure and the second sub-capacitor structure are symmetrical to each other in the vertical direction.

19. The semiconductor package of claim 18,
wherein the through via has a tapered shape of which a horizontal width increases from the top surface of the second substrate to the bottom surface of the second substrate, and
wherein the horizontal width of the through via is about 3 μm to about 20 μm.

20. The semiconductor package of claim 18, further comprising:
a connection bump; and
an insulating adhesive layer surrounding the connection bump,
wherein the second substrate comprises:
a first base substrate; and
a second base substrate arranged on the first base substrate,
wherein the insulating adhesive layer fills a space between the first base substrate and the second base substrate,
wherein the through via comprises:
a first through via extending through the first base substrate; and
a second through via extending through the second base substrate and electrically connected to the first through via with the connection bump therebetween, and
wherein the first through via and the second through via have tapered shapes that are symmetrical to each other with respect to the connection bump.
